(19) United States
(12) Patent Application Publication
(10) Pub. No.: US 2026/0023105 A1
(43) Pub. Date: Jan. 22, 2026

(54) LOCATING A FAULTY SUBSECTION IN A DISTRIBUTION NETWORK

(71) Applicant: Mahdi DAVARPANAH, Tehran (IR)

(72) Inventors: Mahdi DAVARPANAH, Tehran (IR); Mohammad Hasan ZAHEDI, Tehran (IR); Moein ABEDINI, Tehran (IR)

(73) Assignee: Mahdi DAVARPANAH, Tehran (IR)

(21) Appl. No.: 19/340,941

(22) Filed: Sep. 26, 2025

Related U.S. Application Data
(63) Continuation-in-part of application No. PCT/IB2023/053615, filed on Apr. 9, 2023.

(51) Int. Cl. G01R 31/08

(52) U.S. Cl. CPC G01R 31/088; G01R 31/086

(57) ABSTRACT

A method for locating a faulty subsection in a distribution network. The method includes measuring a plurality of voltage signals, obtaining one or more pre-fault negative sequence components and one or more post-fault negative sequence components from the plurality of voltage signals, and detecting the faulty subsection based on the one or more pre-fault negative sequence components and the one or more post-fault negative sequence components. The plurality of voltage signals is measured utilizing a plurality of measurement devices. The plurality of voltage signals is measured from a plurality of distribution transformers in the distribution network. The one or more pre-fault negative sequence components and the one or more post-fault negative sequence components are obtained utilizing one or more processors. The faulty subsection is detected utilizing the one or more processors.

### TECHNICAL FIELD

The present disclosure generally relates to electric power distribution networks, and particularly, to fault location in electric distribution networks.

### BACKGROUND ART

Electrical faults in distribution networks may cause interruption to electric flows, equipment damages, and safety issues. Therefore, fast fault detection and faulty subsection location in distribution networks is necessary to enhance the system reliability and safety. Two types of faults may generally occur in distribution networks, namely, short-circuit and broken conductor faults.

Broken conductor faults may result in zero current in a downstream direction of a medium voltage (MV) feeder. Therefore, conventional methods may use indices that reflect an unbalance current such as maximum to minimum current ratio or a current negative sequence component to detect broken conductor faults. However, computing such indices requires current measurement sensors such as current transformers, resulting in costly fault detection methods. Short-circuit faults, on the other hand, may be detected by overcurrent functions provided by protection relays installed along MV feeders. Protection relays may also detect location of short-circuit faults by voltage measurement functions [U.S. Pat. No. 8,810,251 B2] or impedance measurement functions [U.S. Pat. No. 8,558,551 B2]. Using protection relays also requires some sensors for measuring voltage and current in an MV feeder, resulting in costly fault detection methods.

There is, therefore, a need for a method for fault location in distribution networks without requiring costly sensors for measurement of voltage and current in MV feeders.

### SUMMARY OF THE DISCLOSURE

This summary is intended to provide an overview of the subject matter of the present disclosure, and is not intended to identify essential elements or key elements of the subject matter, nor is it intended to be used to determine the scope of the claimed implementations. The proper scope of the present disclosure may be ascertained from the claims set forth below in view of the detailed description below and the drawings.

In one general aspect, the present disclosure describes an exemplary method for locating a faulty subsection in a distribution network. An exemplary method may include measuring a plurality of voltage signals, obtaining one or more pre-fault negative sequence components and one or more post-fault negative sequence components from the plurality of voltage signals, and detecting the faulty subsection based on the one or more pre-fault negative sequence components and the one or more post-fault negative sequence components. In an exemplary embodiment, the plurality of voltage signals may be measured utilizing a plurality of measurement devices (MDs). In an exemplary embodiment, the plurality of voltage signals may be measured from a plurality of distribution transformers in the distribution network. In an exemplary embodiment, the one or more pre-fault negative sequence components and the one or more post-fault negative sequence components may be obtained utilizing one or more processors. An exemplary faulty subsection may be detected utilizing the one or more processors.

In an exemplary embodiment, obtaining the one or more pre-fault negative sequence components and the one or more post-fault negative sequence components may include computing a plurality of primary fault detection indices (FDIs), transferring one or more voltage signals of the plurality of voltage signals from one or more MDs of the plurality of MDs to a control center, obtaining one or more synchronized voltage signals at the control center, and computing the one or more pre-fault negative sequence components and the one or more post-fault negative sequence components from the one or more synchronized voltage signals. In an exemplary embodiment, the plurality of primary FDIs may be computed by computing an i^{th} primary FDI of the plurality of primary FDIs at an i^{th} MD of the plurality of MDs. An exemplary i^{th} primary FDI may be computed based on an i^{th} voltage signal of the plurality of voltage signals where 1≤i≤N and N is a number of the plurality of MDs. In an exemplary embodiment, the one or more voltage signals may be transferred by transferring each of the plurality of voltage signals from a respective MD of the plurality of MDs responsive to a respective primary FDI of the plurality of primary FDIs being larger than a trigger threshold. In an exemplary embodiment, the one or more synchronized voltage signals may be obtained by synchronizing the one or more voltage signals.

Computing an exemplary i^{th} primary FDI may include computing a local pre-fault negative sequence component, a local post-fault negative sequence component, a local pre-fault positive sequence component, and a local post-fault positive sequence component from the i^{th} voltage signal, computing a pre-fault compensated phasor value of the local pre-fault negative sequence component, computing a post-fault compensated phasor value of the local post-fault negative sequence component, and computing the i^{th} primary FDI based on the pre-fault compensated phasor value and the post-fault compensated phasor value.

In an exemplary embodiment, synchronizing the one or more voltage signals may include synchronizing an m^{th} voltage signal of the one or more voltage signals where 1≤m≤M and M is a number of the one or more voltage signals. Synchronizing an exemplary m^{th} voltage signal may include computing a phase angle difference between a pre-fault positive sequence component of the m^{th} voltage signal and a pre-fault positive sequence component of a reference voltage signal of the one or more voltage signals and obtaining an m^{th} synchronized voltage signal of the one or more synchronized voltage signals based on the phase angle difference. An exemplary m^{th} synchronized voltage signal may be obtained by applying a time shift proportional to the phase angle difference to the m^{th} voltage signal.

Detecting an exemplary faulty subsection may include computing one or more secondary FDIs based on the one or more pre-fault negative sequence components and the one or more post-fault negative sequence components, computing a first threshold and a second threshold based on the one or more secondary FDIs, obtaining a first MD list based on the first threshold, obtaining a second MD list based on the second threshold, and determining the faulty subsection in an MV feeder of the distribution network based on the first MD list and the second MD list. An exemplary first threshold may be smaller than the second threshold. Obtaining an exemplary first MD list may include assigning each of the one or more MDs to the first MD list responsive to a respective secondary FDI of the one or more secondary FDIs being larger than the first threshold and sorting the first MD list in an ascending order. An exemplary first MD list may be sorted according to distances of MDs in the first MD list from a high voltage to medium voltage (HV/MV) substation. An exemplary first MD list may be sorted by sorting MDs of the first MD list in each branch of an MV feeder of the distribution network. Obtaining an exemplary second MD list may include assigning each of the one or more MDs to the second MD list responsive to a respective secondary FDI of the one or more secondary FDIs being larger than the second threshold and sorting the second MD list in an ascending order. An exemplary second MD list may be sorted according to distances of MDs in the second MD list from the HV/MV substation. An exemplary second MD list may be sorted by sorting MDs of the second MD list in each branch of the MV feeder. An exemplary faulty subsection may be detected responsive to a fault occurrence condition being satisfied.

Determining an exemplary faulty subsection may include determining a first faulty subsection of the MV feeder responsive to a first condition being satisfied. An exemplary first condition may include the first MD list being identical to the second MD list and the first MD list including a set of MDs of a single branch of the MV feeder. An exemplary first faulty subsection may include a subsection of the MV feeder between a first MD in the first MD list and one of a junction in an upstream direction of the MV feeder or a closest MD of the plurality of MDs. An exemplary closest MD may include a shortest distance among the plurality of MDs to the first MD in the upstream direction.

Determining an exemplary faulty subsection may further include determining a second faulty subsection of the MV feeder responsive to a second condition being satisfied. An exemplary second condition may include the first MD list being identical to the second MD list and the first MD list including a set of MDs of two or more branches of the MV feeder. An exemplary second faulty subsection may include a common subsection of the two or more branches.

Determining an exemplary faulty subsection may further include determining a third faulty subsection of the MV feeder responsive to a third condition being satisfied. An exemplary third condition may include MDs in the first MD list being in a single branch of the MV feeder and the first MD list being different from the second MD list. An exemplary third faulty subsection may include a subsection of the MV feeder between a first MD in the first MD list and a second MD in the first MD list. An exemplary third faulty subsection may be closer to the first MD than to the second MD.

Computing an exemplary first threshold and an exemplary second threshold may include obtaining a maximum secondary FDI, setting the first threshold equal to 0.9 FDIₘₐₓ where FDIₘₐₓ is the maximum secondary FDI, and setting the second threshold equal to 0.95 FDIₘₐₓ. Obtaining an exemplary maximum secondary FDI may include finding a maximum value of the one or more secondary FDIs.

An exemplary fault occurrence condition may include one of a maximum value of the one or more secondary FDIs remaining larger than 0.4 for at least 30 seconds and an amplitude of a positive sequence component of the one or more voltage signals being less than 0.05 per unit.

Other exemplary systems, methods, features, and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the claims herein.

### BRIEF DESCRIPTION OF DRAWINGS

The drawing figures depict one or more implementations in accord with the present teachings, by way of example only, not by way of limitation. In the figures, like reference numerals refer to the same or similar elements.

FIG. 1A shows a flowchart of a method for locating a faulty subsection in a distribution network, consistent with one or more exemplary embodiments of the present disclosure.

FIG. 1B shows a flowchart of a method for obtaining one or more pre-fault negative sequence components and one or more post-fault negative sequence components, consistent with one or more exemplary embodiments of the present disclosure.

FIG. 1C shows a flowchart of a method for computing a plurality of primary fault detection indices (FDIs), consistent with one or more exemplary embodiments of the present disclosure.

FIG. 1D shows a flowchart of a method for synchronizing one or more voltage signals, consistent with one or more exemplary embodiments of the present disclosure.

FIG. 1E shows a flowchart of a method for detecting a faulty subsection, consistent with one or more exemplary embodiments of the present disclosure.

FIG. 1F shows a flowchart of a method for computing a first threshold and a second threshold, consistent with one or more exemplary embodiments of the present disclosure.

FIG. 1G shows a flowchart of a method for obtaining a first measurement device (MD) list, consistent with one or more exemplary embodiments of the present disclosure.

FIG. 1H shows a flowchart of a method for obtaining a second MD list, consistent with one or more exemplary embodiments of the present disclosure.

FIG. 1I shows a flowchart of a method for determining a faulty subsection, consistent with one or more exemplary embodiments of the present disclosure.

FIG. 2A shows a schematic of a distribution network, consistent with one or more exemplary embodiments of the present disclosure.

FIG. 2B shows a schematic of a broken conductor fault in a simple MV feeder, consistent with one or more exemplary embodiments of the present disclosure.

FIG. 3 shows a high-level functional block diagram of a computer system, consistent with one or more exemplary embodiments of the present disclosure.

FIG. 4 shows a schematic of a distribution network with three branches, consistent with one or more exemplary embodiments of the present disclosure.

FIG. 5 shows FDI values of different MDs when a broken conductor fault is occurred at a first fault point, consistent with one or more exemplary embodiment of the present disclosure.

FIG. 6 shows FDI values of different MDs when a broken conductor fault is occurred at a second fault point, consistent with one or more exemplary embodiment of the present disclosure.

FIG. 7 shows FDI values of different MDs when a broken conductor fault is occurred at a third fault point, consistent with one or more exemplary embodiment of the present disclosure.

FIG. 8 shows FDI values of different MDs when a phase-to-ground short-circuit fault is occurred at a middle of a line, consistent with one or more exemplary embodiment of the present disclosure.

FIG. 9 shows FDI values of different MDs when a phase-to-ground short-circuit fault is occurred at a 10 percent of a line, consistent with one or more exemplary embodiment of the present disclosure.

FIG. 10 shows FDI values of different MDs when a phase-to-phase short-circuit fault is occurred, consistent with one or more exemplary embodiment of the present disclosure.

### DESCRIPTION OF EMBODIMENTS

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

Herein is disclosed an exemplary method for locating a faulty subsection in distribution networks. The method is based on voltage measurements from secondary sides of distribution transformers by a number of measurement devices (MDs) installed across the distribution network. Each exemplary MD measures three-phase voltages from a respective distribution transformer and computes a fault occurrence index (FDI). An exemplary FDI may indicate variation of a negative sequence component of a voltage signal between pre-fault and post-fault time instants. Therefore, a possible fault may be detected when a value of FDI increases and goes higher than a certain threshold. When an FDI of an exemplary MD exceeds a trigger threshold, the MD sends measured voltage signals to a control center, where measurements of all triggered MDs are aggregated. All received voltage signals of triggered MDs are first synchronized for a timely comparison of FDIs among various MDs. After synchronization, another set of FDIs is computed at the control center based on synchronized voltage signals.

Given a broken conductor fault, voltage levels of different phases may become asymmetric, changing a value of a corresponding negative sequence component. Similarly, an exemplary asymmetric short-circuit fault may change a value of a corresponding negative sequence component. Therefore, finding MDs with highest FDIs may lead to detecting a faulty subsection based on locations of corresponding MDs. In doing so, two thresholds based on a maximum value of FDIs are defined, where a first threshold is smaller than a second threshold. A first list of MDs may be obtained by comparing FDIs with the first threshold and a second list of MDs may be obtained by comparing FDIs with the second threshold. MDs in both the first list and the second list are impacted by a fault. Therefore, an exemplary faulty subsection may be detected by comparing elements in the first list and the second list and locations of corresponding MDs.

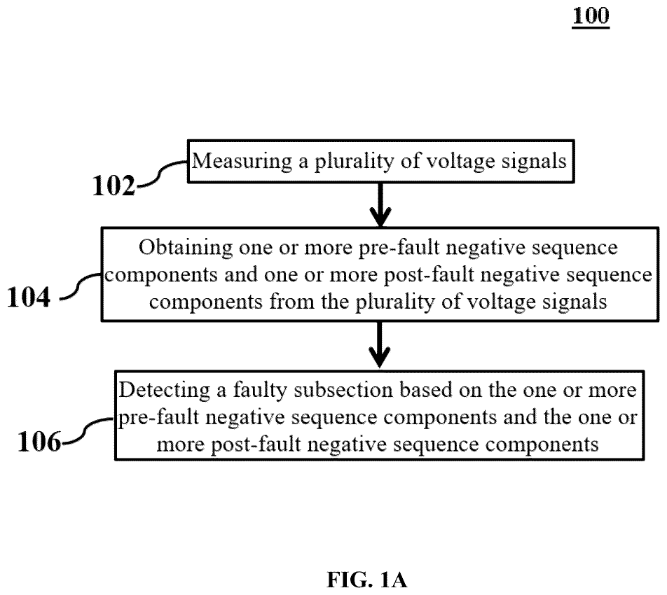

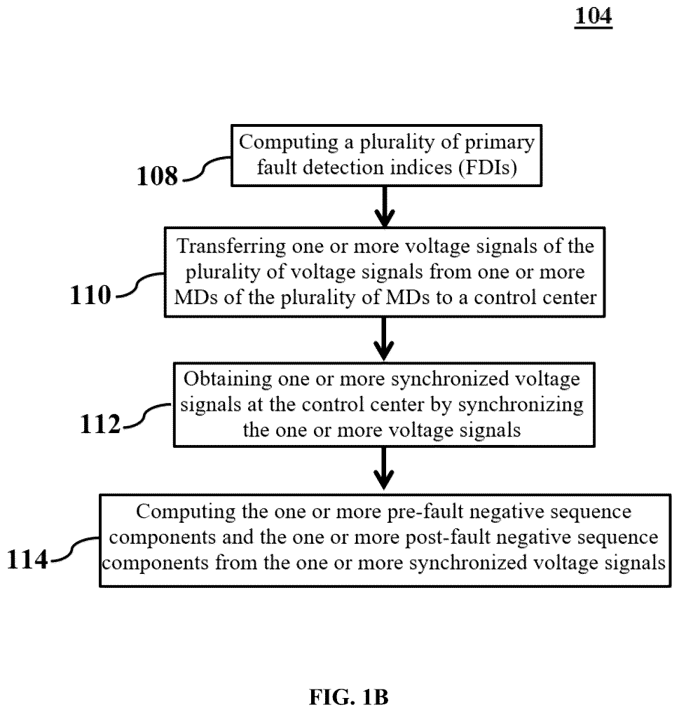

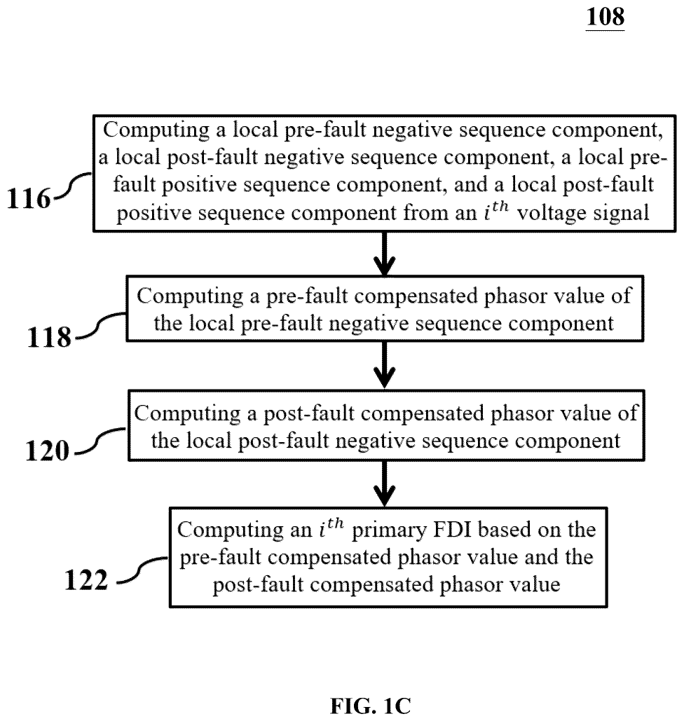

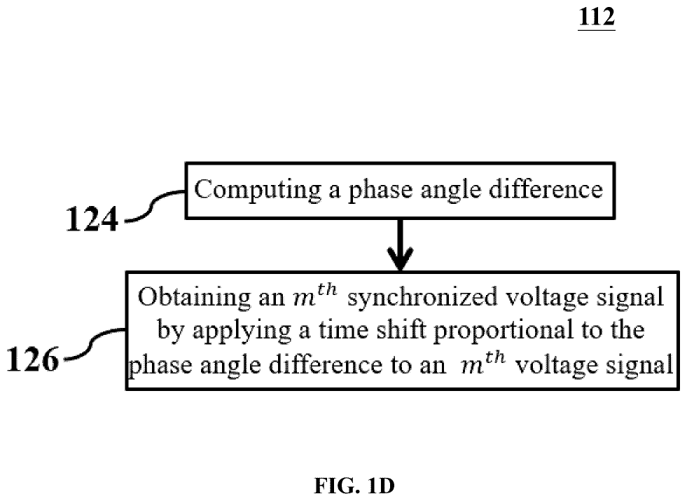

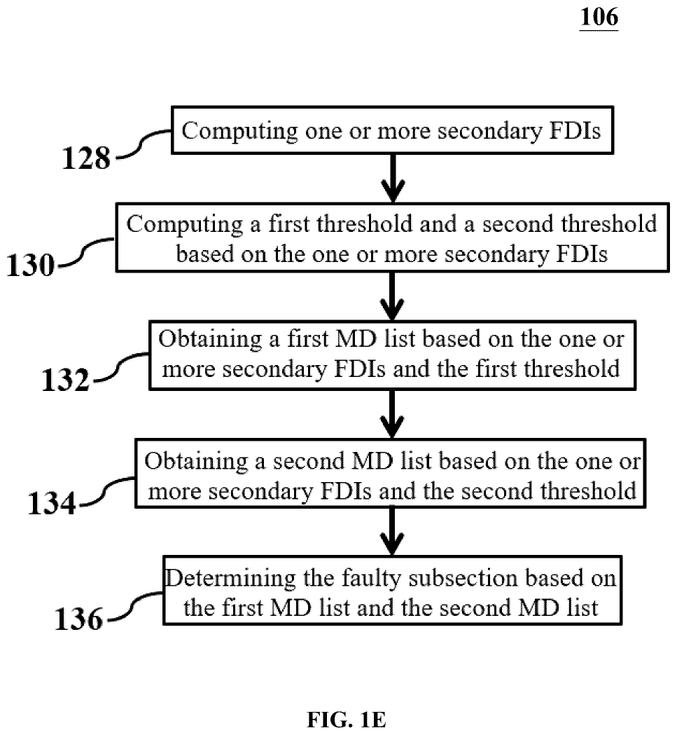

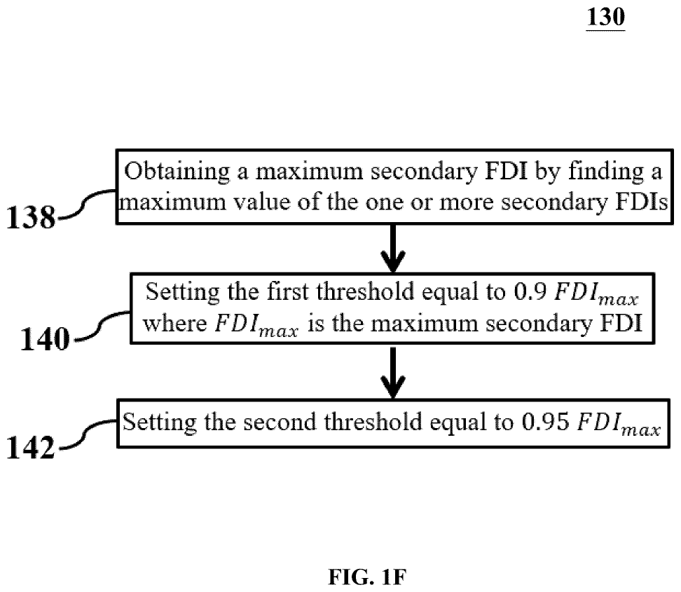

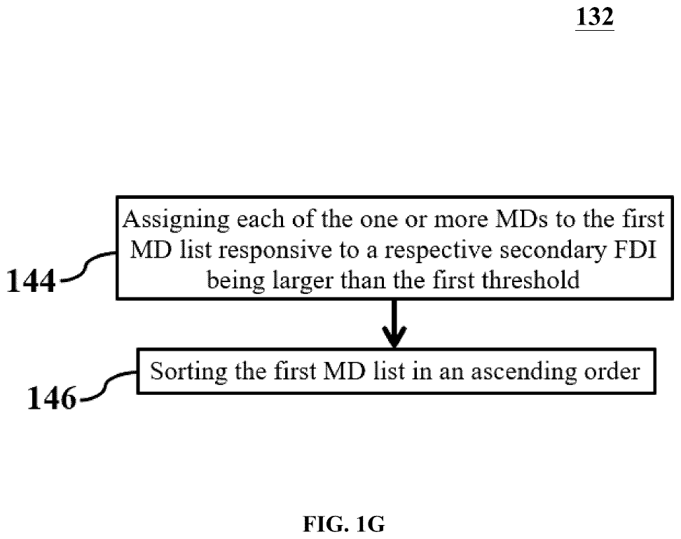

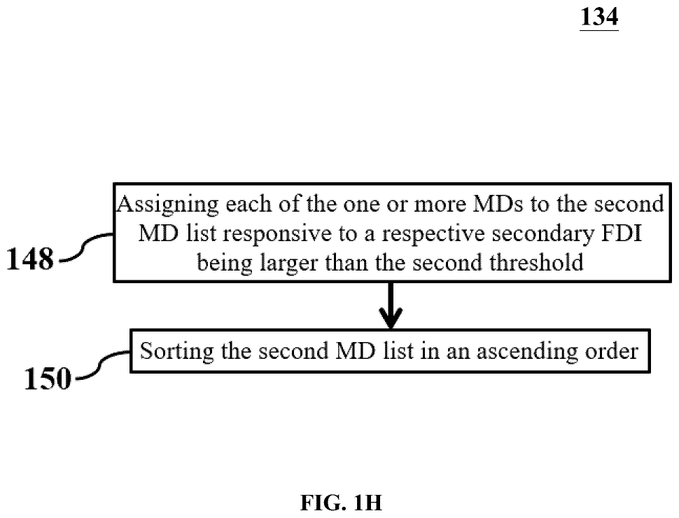

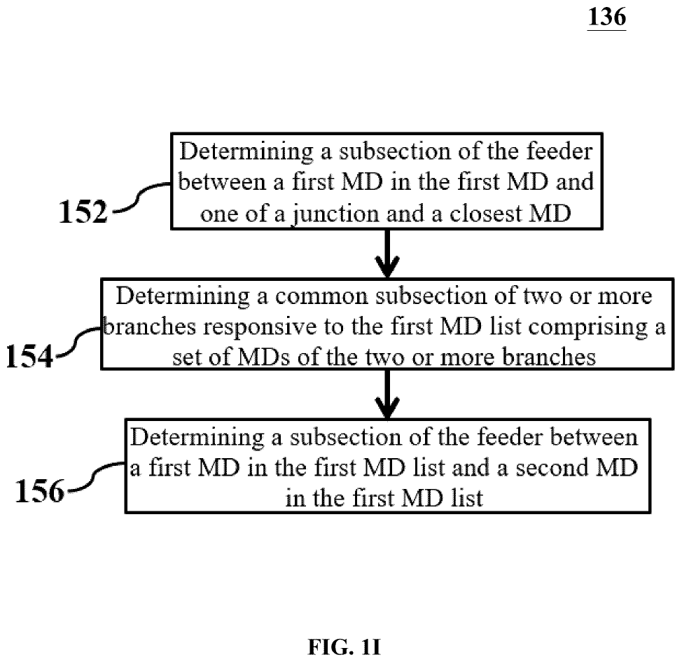

FIG. 1A shows a flowchart of a method for locating a faulty subsection in a distribution network, consistent with one or more exemplary embodiments of the present disclosure. In an exemplary embodiment, a method 100 may include measuring a plurality of voltage signals (step 102), obtaining one or more pre-fault negative sequence components and one or more post-fault negative sequence components from the plurality of voltage signals (step 104), and detecting a faulty subsection based on the one or more pre-fault negative sequence components and the one or more post-fault negative sequence components (step 106). In an exemplary embodiment, method 100 may detect a faulty subsection based on a change in negative sequence component of voltage signals measured by a plurality of MDs. In an exemplary embodiment, each of the plurality of MDs may measure a voltage signal of a three-phase line in a medium voltage (MV) feeder of a distribution network. Then, exemplary pre-fault and post-fault negative sequence components of measured voltage signals may be computed. An exemplary faulty subsection may be finally detected based on relative changes in pre-fault and post-fault values for different MDs and based on locations of MDs in the MV feeder.

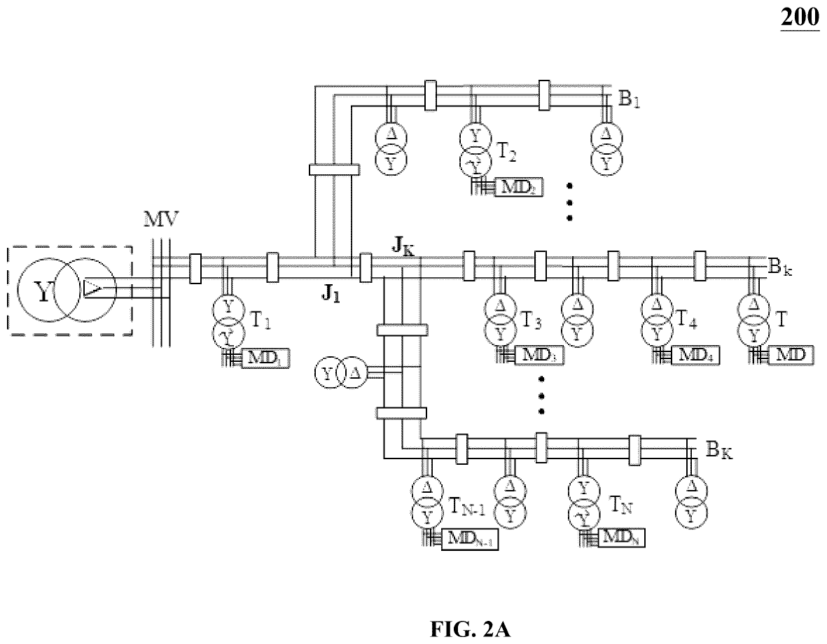

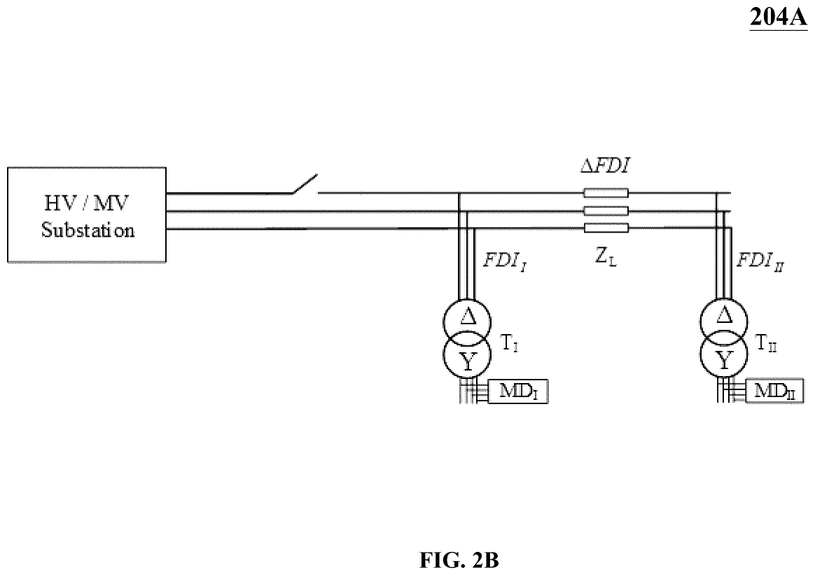

FIG. 2A shows a schematic of a distribution network, consistent with one or more exemplary embodiments of the present disclosure. In an exemplary embodiment, a distribution network 200 may connect a high voltage to MV (HV/MV) substation 202 to a plurality of distribution transformers, such as transformer T₁ to transformer T_{N}, through an MV feeder 204. Referring to FIGS. 1A and 2A, in an exemplary embodiment, different steps of method 100 may be implemented utilizing a plurality of MDs, that is, device MD₁ to device MD_{N}, a number of processors at each of the plurality of MDs, and a control center.

For further detail with respect to step 102, in an exemplary embodiment, the plurality of voltage signals may be measured utilizing the plurality of MDs. In an exemplary embodiment, each of the plurality of voltage signals may be measured by a respective MD of the plurality of MDs. Specifically, in an exemplary embodiment, an i^{th} voltage signal of the plurality of voltage signals may be measured by an i^{th} MD 206 of the plurality of MDs where 1≤i≤N and N is a number of the plurality of MDs. In an exemplary embodiment, MD 206 may include one of a relay, a power quality meter, a power meter, an energy meter, or a phasor measurement unit. An exemplary i^{th} voltage signal may include a three-phase voltage signal. In an exemplary embodiment, MD 206 may measure the i^{th} voltage signal from a secondary side of a distribution transformer 208 of the plurality of distribution transformers. As a result, in an exemplary embodiment, MD 206 may directly measure low voltage (LV) signals and may not require voltage sensors such as voltage transformers or voltage dividers to transform MV signals to LV signals.

MD 206 may measure an exemplary i^{th} voltage signal by sampling a voltage level of each phase at a secondary side of transformer 208. In an exemplary embodiment, MD 206 may sample the voltage level at a sampling frequency fₛ. An exemplary sampling frequency may be set to 1 kHz. As a result, an exemplary i^{th} voltage signal may include three digital signals. Each exemplary digital signal may include samples of a respective phase-to-ground voltage signal. MD 206 may measure an exemplary i^{th} voltage signal at both pre-fault and post-fault time instants. Specifically, an exemplary i^{th} voltage signal may include three vectors of voltage samples from t₁ seconds before a fault time instant to t₂ seconds after the fault time instant, each vector corresponding to samples of a respective phase-to-ground voltage signal.

In further detail regarding step 104, FIG. 1B shows a flowchart of a method for obtaining one or more pre-fault negative sequence components and one or more post-fault negative sequence components, consistent with one or more exemplary embodiments of the present disclosure. Locating an exemplary faulty subsection may be performed by analyzing changes in pre-fault and post-fault negative sequence components of the plurality of voltage signals. In an exemplary embodiment, obtaining the one or more pre-fault negative sequence components and the one or more post-fault negative sequence components may include computing a plurality of primary FDIs (step 108), transferring one or more voltage signals of the plurality of voltage signals from one or more MDs of the plurality of MDs to a control center (step 110), obtaining one or more synchronized voltage signals at the control center (step 112), and computing the one or more pre-fault negative sequence components and the one or more post-fault negative sequence components from the one or more synchronized voltage signals (step 114).

In further detail regarding step 108, FIG. 1C shows a flowchart of a method for computing a plurality of primary FDIs, consistent with one or more exemplary embodiments of the present disclosure. In an exemplary embodiment, each of the plurality of MDs may independently compute a respective primary FDI of the plurality of primary FDIs. Referring to FIGS. 1C and 2A, in an exemplary embodiment, the plurality of primary FDIs may be computed by computing an i^{th} primary FDI of the plurality of primary FDIs at MD 206. An exemplary i^{th} primary FDI may be computed based on the i^{th} voltage signal. Computing an exemplary i^{th} primary FDI may include computing a local pre-fault negative sequence component, a local post-fault negative sequence component, a local pre-fault positive sequence component, and a local post-fault positive sequence component from the i^{th} voltage signal (step 116), computing a pre-fault compensated phasor value of the local pre-fault negative sequence component (step 118), computing a post-fault compensated phasor value of the local post-fault negative sequence component (step 120), and computing the i^{th} primary FDI based on the pre-fault compensated phasor value and the post-fault compensated phasor value (step 122).

For further detail with regard to step 116, an exemplary local pre-fault negative sequence component and the local pre-fault positive sequence component may be computed from the voltage samples of the i^{th} voltage signal at t₁ seconds before the fault time instant. In doing so, an exemplary phasor value of each phase-to-ground voltage of the i^{th} voltage signal may be computed by applying a full power frequency cycle Fourier transform to voltage signals at t₁ seconds before the fault time instant. Next, an exemplary local pre-fault negative sequence component and the local pre-fault positive sequence component may be computed by applying a Fortescue transformation to phasor values of the i^{th} voltage signal obtained from the Fourier transform. In an exemplary embodiment, t₁ seconds may be equal to five power frequency cycles. In an exemplary embodiment, MD 206 may buffer the i^{th} voltage signal and may compute the i^{th} primary FDI in real-time, that is, i.e., after each sampling of the i^{th} voltage signal. When an exemplary possible fault is detected, that is, when a value of the i^{th} primary FDI exceeded a certain threshold at a fault time instant, MD 206 may record the i^{th} voltage signal from t₁ seconds before the fault time instant to t₂ seconds after the fault time instant. An exemplary local post-fault negative sequence component and the local post-fault positive sequence component may be computed from the voltage samples of the i^{th} voltage signal at t₂ seconds after the fault time instant. In doing so, an exemplary phasor value of each phase-to-ground voltage of the i^{th} voltage signal may be computed by applying a full power frequency cycle Fourier transform to voltage signals at t₂ seconds after the fault time instant. Next, an exemplary local post-fault negative sequence component and the local post-fault positive sequence component may be computed by applying a Fortescue transformation to phasor values of the i^{th} voltage signal obtained from the Fourier transform. In an exemplary embodiment, t₂ seconds may be equal to one power frequency cycle.

Distribution transformers may have various vector groups, e.g., Dyn and Yzn vector groups. In addition, an exemplary phase rotation (on both primary and secondary sides) may take place when conductors of MV feeder 204 are connected to MV side terminals of transformer 208. When an exemplary broken conductor fault happens in MV feeder 204 with rated voltage, a voltage induced into a secondary side of transformer 208 is equal to a corresponding rated voltage in only one phase. Moreover, an exemplary rated voltage may be divided into remaining phases. An exemplary voltage division may depend on a vector group and a phase rotation. An exemplary voltage division for different vector groups is shown in Table 1. When an exemplary broken conductor fault happens in phase-U of a Dyn5 distribution transformer, a secondary side middle voltage may be equal to the rated voltage and a voltage induced into two outer phases may be equal to half of the rated voltage.

TABLE 1
Secondary side phase-to-ground voltages after a broken conductor
fault occurrence and corresponding negative sequence component

| | | Secondary-side | | | |
|---|---|---|---|---|---|
| | Broken | voltage (PU) | | | |
| Connection | Phase | Vₐₙ | V_{bn} | V_{cn} | V₁^{post} |
| Dyn5 | W | 1 | −0.7 | −0.3 | 0.51 |
| Dyn5 | U | −0.5 | 1 | −0.5 | 0.5 |
| Yzn5 | W | −0.75 | 1 | −0.25 | 0.52 |
| Yzn5 | V | 0.5 | 0.5 | −1 | 0.5 |

As given in Table 1, an exemplary local post-fault negative sequence component (denoted by V₁^{post}) may be in a range of 0.5 to 0.52 PU after a broken conductor fault. Notably, in an exemplary embodiment, a value of local pre-fault negative sequence component may be limited to 0.02 PU in normal operating conditions. As a result, an exemplary broken fault may radically change a value of negative sequence component of the i^{th} voltage between a pre-fault time instant and a post-fault time instant (from a few 0.01 s PU to about 0.5 PU). Therefore, an exemplary i^{th} primary FDI may be computed based on the local pre-fault negative sequence component and the local post-fault negative sequence component.

In further detail with respect to step 118, an exemplary pre-fault compensated phasor value may be used for computation of the i^{th} primary FDI instead of the local pre-fault negative sequence component. An exemplary pre-fault compensated phasor value of the local pre-fault negative sequence component may be computed according to an operation defined by the following:

$$\overline{{V}_{2}^{pre}} = \vert {V}_{2}^{p r e} \vert ∠ ( {θ}_{V {2}^{p r e}} - {θ}_{V {1}^{p r e}} ) \qquad Equation ( 1 )$$

where:

$$\overline{{V}_{2}^{pre}}$$

the pre-fault compensated phasor value,

$${V}_{2}^{pre}$$

is the local pre-fault negative sequence component,
θ_{V2}_{^{pre}} is a phase angle of

$${V}_{2}^{pre} ,$$

and
θ_{V1}_{^{pre}} is a phase angle of the local pre-fault positive sequence component.

For further detail regarding step 120, an exemplary post-fault compensated phasor value may be used for computation of the i^{th} primary FDI instead of the local post-fault negative sequence component. An exemplary post-fault compensated phasor value of the local post-fault negative sequence component may be computed according to an operation defined by the following:

$$\overline{{V}_{2}^{post}} = \vert {V}_{2}^{post} \vert ∠ ( {θ}_{V {2}^{p o s t}} - {θ}_{V {1}^{p o s t}} ) \qquad Equation ( 2 )$$

where:

$$\overline{{V}_{2}^{post}}$$

is the post-fault compensated phasor value,

$${V}_{2}^{post}$$

is the local post-fault negative sequence component,
θ_{V2}_{^{post}} is a phase angle of

$${V}_{2}^{post} ,$$

and
θ_{V1}_{^{post}} is a phase angle of the local post-fault positive sequence component.

In further detail with regard to step 122, an exemplary i^{th} primary FDI may be computed according to an operation defined by the following:

$${FDI}_{i} = \frac{\vert \overline{{V}_{2}^{pre}} - \overline{{V}_{2}^{post}} \vert}{\vert {V}_{1}^{pre} \vert} \qquad Equation ( 3 )$$

where FDIᵢ is the i^{th} primary FDI and

$${V}_{1}^{pre}$$

is the local pre-fault positive sequence component. According to Equation (3), an exemplary i^{th} primary FDI may be regarded as a normalized value of a change in negative sequence components of the i^{th} voltage signal between a pre-fault time instant and a post-fault time instant. Therefore, in an exemplary embodiment, higher values of FDI, may indicate a higher chance for a fault impacting MD 206.

Referring to FIGS. 1B and 2A, in an exemplary embodiment, step 110 may include transferring one or more voltage signals of the plurality of voltage signals. In an exemplary embodiment, the one or more voltage signals may be transferred by transferring each of the plurality of voltage signals from a respective MD of the plurality of MDs responsive to a respective primary FDI of the plurality of primary FDIs being larger than a trigger threshold. Specifically, an exemplary i^{th} primary FDI may be transferred from MD 206 to the control center responsive to the i^{th} primary FDI being larger than the trigger threshold. An exemplary control center may include a dispatching center of distribution network 200.

In an exemplary embodiment, MD 206 fault detector may operate when an exemplary i^{th} primary FDI becomes higher than the trigger threshold, indicating occurrence of a fault or a disturbance in MV feeder 204, and thus, the i^{th} voltage signal may be recorded and sent to the control center. An exemplary i^{th} voltage signal may include three-phase voltages measured from secondary side of transformer 208 with sampling frequency of fₛ(e.g., 1000 Hz), a pre-triggering duration of more than t₂ (e.g., 0.5 s), and a post-triggering duration of more than t₁ (e.g., 3.5 s).

An exemplary trigger threshold may be adjusted relatively sensitive to guarantee that MD 206 is properly triggered after a fault occurrence. In doing so, in an exemplary embodiment, MD 206 may also be triggered under system disturbances such as changing a topology of MV feeder 204, that is, connecting/disconnecting a branch or switching on/off a distribution transformer or a large load. Therefore, in an exemplary embodiment, discrimination between a fault and a system disturbance may be performed before computations regarding a fault location. In an exemplary embodiment, discrimination between a fault and a system disturbance may be performed at the control center along with required off-line computations for fault location detection. Hence, in an exemplary embodiment, triggering of MD 206 under system transient states may not negatively impact a precision of method 100.

An exemplary trigger threshold may be determined so that MD 206 may not be triggered by a sudden change in a negative sequence component current with amplitude of up to 1% of a maximum load current. An exemplary trigger threshold may be set to be equal to a relative change in voltage negative sequence components seen at a location of MD 206. When an exemplary maximum load current passing through MV feeder 204 is equal to 150 A and a distance between a location of MD 206 and HV/MV substation 202 is equal to L=12 km, the trigger threshold may be calculated according to an operation defined by the following:

$${FDI}_{Trg} \geq \frac{0.01 \times {I}_{max} \times L \times Z}{\frac{{V}_{n}}{\sqrt{3}}} = \frac{1 \% \times 150 ( A ) \times 12 ( km ) \times 0.5 ( Ω / km )}{20000 ( V ) / \sqrt{3}} = 0.078 \% \qquad Equation ( 4 )$$

where:
FDI_{Trg} is the trigger threshold,
Iₘₐₓ is the maximum load current, and
Z is an impedance of lines in MV feeder 204 per km.

According to Equation (4), an exemplary FDI_{Trg} may be set to 0.1%, taking a margin into account. An exemplary value of L×Z×Iₘₐₓ may be kept limited due to a voltage drop restriction along MV feeder 204. Therefore, in an exemplary embodiment, when one of L, Z, or Iₘₐₓ is beyond values in Equation (4), another parameter may become more limited. In an exemplary embodiment, when a line length L is more than 12 km, maximum load current Iₘₐₓ may be less than 150 A. In addition, when an exemplary rated voltage of distribution network 200 is less than 20 kV, a length of MV feeder 204 may be shorter. Besides, at an exemplary higher rated voltage, a longer feeder length may be used. Consequently, an exemplary value FDI_{Trg}=0.1% may be suitable for typical MV feeders.

In an exemplary embodiment, when MD 206 is triggered, that is, when i^{th} primary FDI exceeds the trigger threshold, samples of the i^{th} voltage signal may be transferred to the control center. Transferring an exemplary i^{th} voltage signal may include sending the i^{th} voltage signal of MD 206 and receiving the i^{th} voltage signal at the control center. In an exemplary embodiment, MD 206 may timestamp the i^{th} voltage signal to be used for synchronization in subsequent steps of method 100. An exemplary timestamping may be performed based on a simple network time protocol (SNTP). An exemplary i^{th} voltage signal may be sent and received utilizing a cellular communication network.

For further detail with respect to step 112, in an exemplary embodiment, the one or more synchronized voltage signals may be obtained by synchronizing the one or more voltage signals. Since the one or more MDs may be triggered in different instants, the one or more voltage signals may be of different time-shifts with respect to each other, based on timestamps added to the one or more voltage signals. In an exemplary embodiment, synchronizing the one or more voltage signals may include synchronizing an m^{th} voltage signal of the one or more voltage signals where 1≤m≤M and M is a number of the one or more voltage signals. Synchronizing an exemplary m^{th} voltage signal may include a two-step process. In a first step, an exemplary m^{th} SNTP-based synchronized voltage signal of one or more SNTP-based synchronized voltage signals may be obtained by using a timestamp of the m^{th} voltage signal to synchronize the one or more voltage signals with the control center based on SNTP. In doing so, exemplary time shifts of the one or more voltage signals may be compensated for at the control center to have the same beginning time for the one or more voltage signals. An exemplary SNTP may result in a coarse synchronization in order of a few milliseconds. In a second step and to achieve a fine synchronization, angle phase data of the one or more SNTP-based synchronized voltage signals may be exploited, as described in the following.

FIG. 1D shows a flowchart of a method for synchronizing one or more voltage signals, consistent with one or more exemplary embodiments of the present disclosure. Referring to FIGS. 1D and 2A, in an exemplary embodiment, synchronizing an exemplary m^{th} voltage signal in step 112 may include computing a phase angle difference between a pre-fault positive sequence component of the m^{th} voltage signal and a pre-fault positive sequence component of a reference voltage signal of the one or more voltage signals (step 124) and obtaining an m^{th} synchronized voltage signal of the one or more synchronized voltage signals based on the phase angle difference (step 126).

In further detail regarding step 124, an exemplary phase angle difference between different MDs connected to MV feeder 204 may be negligible under normal conditions. Therefore, exemplary pre-fault samples of the one or more SNTP-based synchronized voltage signals may be exploited for a fine time synchronization. In doing so, exemplary phasor values of the one or more SNTP-based synchronized voltage signals may be calculated, e.g., by the Fourier transform. An exemplary first triggered MD of the one or more MDs may be considered as a reference MD and a pre-fault positive sequence component of a reference voltage signal of the reference MD may be computed at t₁ seconds before a fault detection instant. Exemplary voltage positive sequence components of other MDs of the one or more MDs may be calculated at the same time with the reference MD. An exemplary phase angle difference, denoted by Δϕ, may include phase angle difference between the pre-fault positive sequence component of the reference MD with a pre-fault positive sequence component of the m^{th} MD of the one or more MDs.

For further detail with regard to step 126, an exemplary m^{th} synchronized voltage signal may be obtained by applying a time shift proportional to phase angle difference Δϕ to the m^{th} SNTP-based synchronized voltage signal. An exemplary time shift may be obtained according to an operation defined by the following:

$$Δ t = \frac{Δ ϕ}{360} \times \frac{{f}_{n}}{{f}_{s}} \qquad Equation ( 5 )$$

where Δt is the time shift and fₙ is a frequency of distribution network 200.

Referring again to FIG. 1B, in an exemplary embodiment, step 114 may include computing the one or more pre-fault negative sequence components and the one or more post-fault negative sequence components. In an exemplary embodiment, each of the one or more pre-fault negative sequence components may include a negative sequence component of a respective synchronized voltage signal of the one or more voltage signals computed at t₁ seconds before a fault detection time instant. In an exemplary embodiment, each of the one or more post-fault negative sequence components may include a negative sequence component of a respective synchronized voltage signal of the one or more voltage signals computed at t₂ seconds after the fault detection time instant. In doing so, an exemplary phasor value of each phase-to-ground voltage of the m^{th} synchronized voltage signal may be computed by applying a full power frequency cycle Fourier transform to voltage signals at t₁ seconds before the fault time instant. Next, an exemplary m^{th} pre-fault negative sequence component of the one or more pre-fault negative sequence components may be computed by applying the Fortescue transformation to phasor values obtained from the Fourier transform. Similarly, an exemplary m^{th} post-fault negative sequence component of the one or more post-fault negative sequence components may be computed by applying the Fortescue transformation to phasor values of the m^{th} voltage signal at t₂ seconds after the fault detection time instant.

Referring again to FIG. 1A, in an exemplary embodiment, step 106 may include detecting a faulty subsection based on the one or more pre-fault negative sequence components and the one or more post-fault negative sequence components. In further detail with respect to step 106, FIG. 1E shows a flowchart of a method for detecting a faulty subsection, consistent with one or more exemplary embodiments of the present disclosure. Referring to FIGS. 1E and 2A, detecting an exemplary faulty subsection in step 106 may include computing one or more secondary FDIs based on the one or more pre-fault negative sequence components and the one or more post-fault negative sequence components (step 128), computing a first threshold and a second threshold based on the one or more secondary FDIs (step 130), obtaining a first MD list based on the first threshold (step 132), obtaining a second MD list based on the second threshold (step 134), and determining the faulty subsection in MV feeder 204 based on the first MD list and the second MD list (step 136).

For further detail regarding step 128, computing the one or more secondary FDIs may be similar to computing the plurality of primary FDIs. Specifically, an m^{th} secondary FDI of the one or more secondary FDIs may be computed according to Equation (3) by using the m^{th} pre-fault negative sequence component and the m^{th} post-fault negative sequence component computed from the m^{th} synchronized voltage signal. Besides, in an exemplary embodiment, computing the one or more secondary FDIs may further include computing an m^{th} pre-fault positive sequence component and an m^{th} post-fault positive sequence component from the m^{th} synchronized voltage signal, similar to step 116. In other words, in an exemplary embodiment, the one or more secondary FDIs may include index values computed from synchronized voltage signals, in contrast to the plurality of primary FDIs that are computed from the plurality of voltage signals.

In further detail with regard to step 130, FIG. 1F shows a flowchart of a method for computing a first threshold and a second threshold, consistent with one or more exemplary embodiments of the present disclosure. Computing an exemplary first threshold and an exemplary second threshold may include obtaining a maximum secondary FDI (step 138), setting the first threshold equal to 0.9 FDIₘₐₓ where FDIₘₐₓ is the maximum secondary FDI (step 140), and setting the second threshold equal to 0.95 FDIₘₐₓ (step 142).

Referring to FIGS. 1F and 2A, an exemplary first threshold and an exemplary second threshold may be separately computed for each of the one or more MDs based on an impedance of a section in MV feeder 204 between each MD and an upstream MD as well as a maximum current passing through the section. Exemplary thresholds may also be set to be equal for the one or more MDs. As given in Table 1, exemplary secondary FDI values may be in a range of 0.5 to 0.52 PU after a broken conductor fault. As a result, exemplary FDI values of different MDs may differ up to 2% for an upstream broken conductor fault. Therefore, exemplary secondary FDI values that are about a maximum value of secondary FDI values may be utilized for detection of MDs impacted by a fault.

For further detail with respect to step 138, in an exemplary embodiment, obtaining an exemplary maximum secondary FDI may include finding a maximum value of the one or more secondary FDIs. An exemplary MD with the maximum secondary FDI may be highly impacted by broken conductor fault or an asymmetric short-circuit fault. However, an exemplary MD with the maximum secondary FDI may not necessarily indicate a first MD installed after the faulty subsection. Therefore, exemplary values of the first threshold and the second threshold may be set such that all MDs impacted by a fault are detectable.

In further detail regarding step 140, FIG. 2B shows a schematic of a broken conductor fault in a simple MV feeder, consistent with one or more exemplary embodiments of the present disclosure. An exemplary FDI value computed using voltages of a transformer T₁ is assumed to be equal to FDI_{I} for an asymmetric short-circuit fault or a broken conductor fault. Similarly, an exemplary FDI value computed for a transformer T_{II} is denoted by FDI_{II}. By ignoring low voltage loads and considering similar vector groups for the plurality of distribution transformers, all downstream MDs relative to a faulty subsection may include the same FDI value, that is, FDIₘₐₓ. In an exemplary embodiment, when a phase U is interrupted along an MV feeder 204A, FDI values calculated for both downstream transformers with identical vector group of Dyn5, i.e., transformer T_{I} and transformer T_{II}, may be equal to FDI_{I}=FDI_{II}=0.5.

Under practical circumstances, FDI_{I} may be different from FDI_{II}. Specifically, exemplary unbalanced low voltage loads may generate a current negative sequence component passing through MV feeder 204A under a normal operation condition. Therefore, an exemplary voltage drop may cause different FDI_{I} and FDI_{II} for both normal and faulty circumstances. Besides, according to Table 1, exemplary FDI values under a broken conductor fault may vary up to 2%. As a result, an exemplary difference of FDI_{I} and FDI_{II} may need to be characterized. An exemplary value of FDI_{II} may be calculated based on FDI_{I} according to an operation defined by the following:

$${FDI}_{II} = {FDI}_{I} + Δ FDI \qquad Equation ( 6 )$$

where ΔFDI denotes a relative negative sequence component of voltage drop across an impedance of a subsection 210 of MV feeder 204A between transformer T_{I} and transformer T_{II}. An exemplary value of ΔFDI may be calculated according to an operation defined by the following:

$$Δ FDI = \frac{Δ {I}_{2} \times {Z}_{L}}{{V}_{TI}} \qquad Equation ( 7 )$$

where:
ΔI₂ is a change in negative sequence component of a current passing through transformer Tu after the fault occurrence,
Z_{L} is an impedance of lines in subsection 210, and
V_{TI} is a rated phase-to-ground voltage of distribution network 200.

In an exemplary embodiment, under an assumption of a constant impedance load model, ΔI₂ may be proportional to a change in voltage negative sequence component, that is, ΔV₂. Besides, an exemplary value of FDI given in Equation (3) may be related to ΔV₂. Hence, a change in a current negative sequence component may be obtained according to an operation defined by the following:

$$Δ {I}_{2} = k \times {FDI}_{1} \times {I}_{L max} \qquad Equation ( 8 )$$

where k denotes a safety factor. An exemplary safety factor may be set equal to 1.3. Besides, I_{Lmax} is an exemplary maximum load current passing through a downstream of MV feeder 204A at a location of transformer T_{I}. An exemplary maximum load current may be assumed to be equal to 150 amps. An exemplary value of ΔFDI may be obtained by combining Equation (7) and Equation (8), according to an operation defined by the following:

$$Δ FDI = {FDI}_{I} \times \frac{k \times {I}_{L max \times {Z}_{L}}}{{V}_{n} / \sqrt{3}} \qquad Equation ( 9 )$$

In an exemplary embodiment, subsection 210 may be of 7 km length, and an impedance of subsection 210 may be assumed to be 3.5Ω. Moreover, Vₙ may include an exemplary rated phase-to-phase voltage equal to 20 kV. As a result, an exemplary relative negative sequence component of voltage drop may be equal to ΔFDI=0.06×FDI_{I}. Considering effects of a vector group difference and an unbalance load, and taking a safety margin into account, an exemplary maximum difference between FDIs of two consecutive MDs in a faulty subsection of MV feeder 204A, i.e., FDI_{I} and FDI_{II}, may be considered equal to 0.1 times of a value of FDI_{I}. Thus, an exemplary first threshold for detecting all MDs impacted by a fault in MV feeder 204A may be determined according to an operation defined by the following:

$${FDI}_{Th 1} = {FDI}_{max} - 0.1 \times Δ FDI ≃ 0. 9 \times {FDI}_{max} \qquad Equation ( 10 )$$

For further detail with regard to step 142, an exemplary distance between two consecutive MDs may be relatively large. Hence, discrimination of faults adjacent to an exemplary MD may have a significant influence on reducing the duration of an exact fault location by using visual inspections. When an exemplary fault occurs adjacent to a location of an MD, a difference of FDI values between the MD and the next downstream MD in a faulty subsection may decrease. Therefore, an exemplary second threshold may be of a larger value as compared with the first threshold. Specifically, an exemplary second threshold may be set according to an operation defined by the following:

$${FDI}_{T h 2} = 0.95 \times {FDI}_{max} \qquad Equation ( 11 )$$

Referring to FIG. 1E, step 132 may include obtaining an exemplary first MD list. In further detail with respect to step 132, FIG. 1G shows a flowchart of a method for obtaining a first MD list, consistent with one or more exemplary embodiments of the present disclosure. Obtaining an exemplary first MD list may include assigning each of the one or more MDs to the first MD list responsive to a respective secondary FDI of the one or more secondary FDIs being larger than the first threshold (step 144) and sorting the first MD list in an ascending order (step 146).

Referring to FIGS. 1G and 2A and for further detail regarding step 144, an exemplary first MD list may include a number of MDs in various sections of MV feeder 204 that are influenced by one of a broken conductor fault or a short-circuit fault. Exemplary MDs with FDIs larger than the first threshold may be impacted by a fault in MV feeder 204. A location of each exemplary MD in the first MD list may be determined according to a topology of MV feeder 204. Specifically, exemplary MDs in each branch of MV feeder 204 may be determined according to a distance of each MD with HV/MV substation 202. Therefore, an exemplary faulty subsection may be detected according to relative locations of MDs in the first MD list.

In further detail with regard to step 146, an exemplary first MD list may be sorted according to distances of MDs in the first MD list with HV/MV substation 202. An exemplary first MD list may be sorted by sorting MDs of the first MD list in each branch of MV feeder 204. An exemplary first MD list may be sorted according to a topology of MV feeder 204. An exemplary topology of MV feeder 204 may be identified by graph theory. In doing so, a list of MDs connected to secondary sides of distribution transformers in each branch may be generated. Specifically, in an exemplary embodiment, a branch Bₖ may be scanned from a receiving end to a sending end (i.e., a point of connection to HV/MV substation 202) and all MDs connected to branch Bₖ may be listed in a k^{th} branch list where 1≤k≤K and K is a number of branches of MV feeder 204. Then, exemplary MDs in the first MD list may be sorted according to orders of MDs in respective branch lists. In other words, when exemplary MDs in the first MD list belong to several branches of MV feeder 204, a respective ordered MD list may be generated for MDs in each branch list. Specifically, a k^{th} ordered MD list may be generated for MDs that are in the first MD list and are also in the k^{th} branch. Therefore, an exemplary first MD list may include several ordered MD lists, each including MDs in a respective branch of MV feeder 204. When an exemplary fault impacts MDs in branch Bₖ, exemplary MDs in the first MD list may indicate a faulty subsection of MV feeder 204 because the faulty subsection may include a subsection of MV feeder 204 in branch Bₖ that includes MDs that are present in both the k^{th} branch list and the first MD list.

Referring to FIG. 1E, step 134 may include obtaining an exemplary second MD list. In further detail with respect to step 134, FIG. 1H shows a flowchart of a method for obtaining a second MD list, consistent with one or more exemplary embodiments of the present disclosure. Obtaining an exemplary second MD list may include assigning each of the one or more MDs to the second MD list responsive to a respective secondary FDI of the one or more secondary FDIs being larger than the second threshold (step 148) and sorting the second MD list in an ascending order (step 150).

For further detail regarding step 148, assigning each of the one or more MDs to an exemplary second MD list in step 148 may be similar to assigning each of the one or more MDs to the first MD list in step 144, except for comparing secondary FDIs with the second threshold instead of the first threshold. In further detail with regard to step 150, sorting an exemplary second MD list in the ascending order in step 150 may be similar to sorting the first MD list in the ascending order in step 146.

Referring again to FIGS. 1E and 2A, step 136 may include determining an exemplary faulty subsection. An exemplary faulty subsection may be detected responsive to a fault occurrence condition being satisfied. An exemplary trigger threshold may be determined very sensitively, that is, a value of trigger threshold may be very smaller than typical values of FDIs when a fault occurs in MV feeder 204. Thus, in an exemplary embodiment, transients during a normal operation of distribution network 200, such as load or branch switching, may lead to triggering one or more MDs and sending corresponding voltage signals to the control center. To prevent a false alarm in transient situations, fault occurrence along MV feeder 204 may be verified before determination a faulty subsection. To do so, an exemplary fault occurrence condition may automatically be evaluated at the control center. An exemplary fault occurrence condition may include one of a maximum value of the one or more secondary FDIs remaining larger than 0.4 for at least 30 seconds and an amplitude of a positive sequence component of the one or more voltage signals being less than 0.05 PU. When an exemplary broken conductor fault happens in MV feeder 204, a value of FDIₘₐₓ may be larger than 0.4 because, according to Table 1, an expected value of FDIs under a broken conductor fault is about 0.5. Applying a safety margin may result in an exemplary threshold equal to 0.4. Under an exemplary broken conductor fault, a value of FDIₘₐₓ may remain larger than 0.4 for t₃ seconds. A value of t₃ may be adjusted based on a strategy of the broken conductor fault detection. In most systems, no protection scheme may be used for automatically fast clearing of such a fault. As a result, a value of t₃ may be adjusted to be 30 second. When an exemplary asymmetrical short-circuit fault happens in MV feeder 204, a protection device may operate and may clear the asymmetrical short-circuit fault by partially or totally disconnecting MV feeder 204. Therefore, following exemplary conditions may be satisfied. First, an amplitude of a voltage positive sequence component of MDs may be almost zero, that is, less than 0.05 PU. Second, an operation signal of a protection device along MV feeder 204 may be received at the control center when an overcurrent function based on negative or zero sequence components of a current passing through a protection device at the beginning of MV feeder 204 is issued a pickup signal.

In further detail with regard to step 136, FIG. 1I shows a flowchart of a method for determining a faulty subsection, consistent with one or more exemplary embodiments of the present disclosure. Referring to FIGS. 1I and 2A, determining an exemplary faulty subsection may include determining a first faulty subsection of MV feeder 204 responsive to a first condition being satisfied (step 152). An exemplary first condition may include the first MD list being identical to the second MD list and the first MD list including a set of MDs of a single branch of MV feeder 204. An exemplary first faulty subsection may include a subsection of MV feeder 204 between a first MD in the first MD list and one of a junction in an upstream direction of MV feeder 204 or a closest MD of the plurality of MDs. An exemplary closest MD may include a shortest distance among the plurality of MDs in the upstream direction to the first MD.

An exemplary fault may occur in a subsection between a transformer T₃ and a junction Jₖ. As a result, in an exemplary embodiment, the first MD list and the second MD list may be identical and may be equal to [MD₃, MD₄, MD 206]. Therefore, an exemplary first faulty subsection may include a subsection of MV feeder 204 between device MD₃ and one of junction Jₖ or a device MD₁, because device MD₁ may be of a higher order than device MD₃ in the k^{th} branch list. Since junction Jₖ is closer to device MD₃ than device MD₁, an exemplary first faulty subsection may be equal to the subsection of MV feeder 204 between device MD₃ and junction Jₖ.

An exemplary fault may occur in a subsection between transformer T₃ and a transformer T₄. As a result, in an exemplary embodiment, the first MD list and the second MD list may be identical and may be equal to [MD₄, MD 206]. Therefore, an exemplary first faulty subsection may include a subsection of MV feeder 204 between device MD₄ and a closest MD to device MD₄ in an upstream of MV feeder 204, that is, device MD₃.

Determining an exemplary faulty subsection may include determining a second faulty subsection of MV feeder 204 responsive to a second condition being satisfied (step 154). An exemplary second condition may include the first MD list being identical to the second MD list and the first MD list including a set of MDs of two or more branches of MV feeder 204. An exemplary second faulty subsection may include a common subsection of the two or more branches. When an exemplary fault occurs in the common subsection of two or more branches of MV feeder 204, FDI values of MDs from different branches may be higher than the first threshold and the second threshold. Therefore, an exemplary faulty subsection may be found by finding a common subsection of branches of MDs that are present in both the first MD list and the second MD list.

An exemplary fault may occur in a subsection of MV feeder 204 between a junction J₁ and junction Jₖ. As a result, exemplary MDs of a branch Bₖ and a branch B_{K} of MV feeder 204 may be present in both the first MD list and the second MD list. In other words, in an exemplary embodiment, the first MD list and the second MD list may be identical and may include [MD₃, MD₄, MD 206, MD_{N-1}, MD_{N}]. As a result, an exemplary second faulty subsection may include a subsection of branches that have MDs in the first MD list and the second MD list, i.e., branch Bₖ and branch B_{K}. In addition, in an exemplary embodiment, a first MD of the first MD list belonging to branch Bₖ may include device MD₃. Thus, an exemplary second faulty subsection may be concluded to be in between device MD₃ and device MD₁ along the branch Bₖ. Besides, in an exemplary embodiment, a first MD of the first MD list belonging to branch Bₖ may include device MD_{N-1}. Thus, an exemplary second faulty subsection may also be concluded to be in between device MD_{N-1} and device MD₁ along the branch Bₖ. On the other hand, none of exemplary MDs belonging to B₁ may exist in the first MD list. As a result, an exemplary second faulty subsection may not be in between device MD₂ and device MD₁. Accordingly, an exemplary final second faulty subsection, which is the common subsection of the above mentioned second faulty subsections, may be deduced to be in between junction J₁ and junction Jₖ.

Determining an exemplary faulty subsection may further include determining a third faulty subsection of MV feeder 204 responsive to a third condition being satisfied (step 156). An exemplary third condition may include MDs in the first MD list being in a single branch of the MV feeder and the first MD list being different from the second MD list. An exemplary third faulty subsection may include a subsection of MV feeder 204 between a first MD in the first MD list and a second MD in the first MD list. An exemplary third faulty subsection may be closer to the first MD than to the second MD.

An exemplary asymmetric short-circuit fault may occur in subsection of MV feeder 204 between device MD₃ and device MD₄. As a result, an exemplary FDI value of device MD₄ or a consecutive MD in a downstream of device MD₄, that is, MD 206, may be equal to FDIₘₐₓ. An exemplary value of device MD₃ may also be high, but it may be less than FDIₘₐₓ. Thus, an exemplary first MD list may be equal to [MD₃, MD₄, MD 206] while an exemplary second MD list may be equal to [MD₄, MD 206]. Since the first MD list is different from the second MD list, an exemplary third faulty subsection may be deduced to be in between the first MD in the first MD list, that is, device MD₃, and the second MD in the first MD list, that is, device MD₄. In addition, an exemplary fault location may be closer to device MD₃ rather than device MD₄.

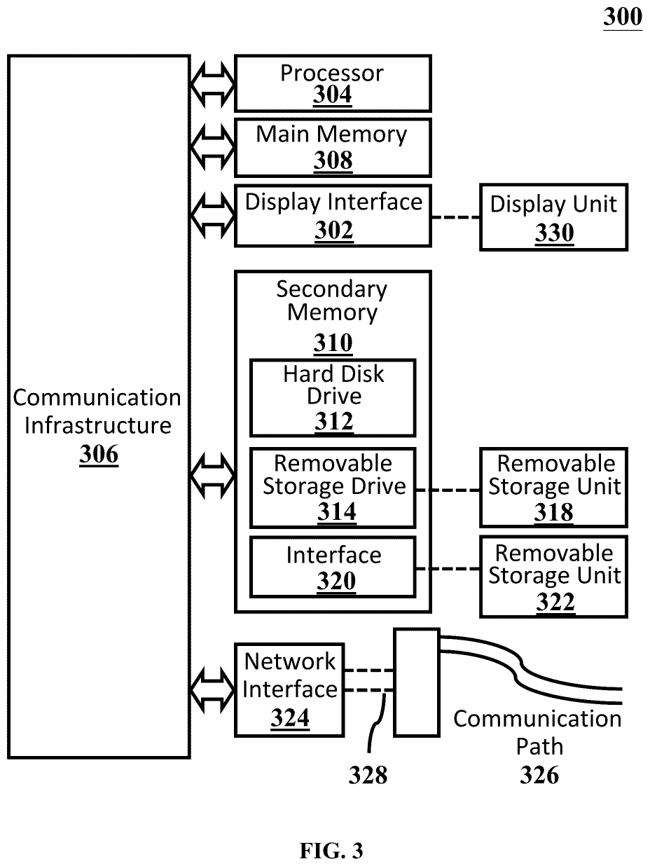

FIG. 3 shows an example computer system 300 in which an embodiment of the present invention, or portions thereof, may be implemented as computer-readable code, consistent with exemplary embodiments of the present disclosure. For example, different steps of method 100 may be implemented in computer system 300 using hardware, software, firmware, tangible computer readable media having instructions stored thereon, or a combination thereof and may be implemented in one or more computer systems or other processing systems. Hardware, software, or any combination of such may embody any of the modules and components in FIGS. 1A-2B.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 300. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multi-processor machines. In addition, in some embodiments the order of operations may be rearranged without departing from the spirit of the disclosed subject matter.

Processor device 304 may be a special purpose (e.g., a graphical processing unit) or a general-purpose processor device. As will be appreciated by persons skilled in the relevant art, processor device 304 may also be a single processor in a multi-core/multiprocessor system, such system operating alone, or in a cluster of computing devices operating in a cluster or server farm. Processor device 304 may be connected to a communication infrastructure 306, for example, a bus, message queue, network, or multi-core message-passing scheme.

In an exemplary embodiment, computer system 300 may include a display interface 302, for example a video connector, to transfer data to a display unit 330, for example, a monitor. Computer system 300 may also include a main memory 308, for example, random access memory (RAM), and may also include a secondary memory 310. Secondary memory 310 may include, for example, a hard disk drive 312, and a removable storage drive 314. Removable storage drive 314 may include a floppy disk drive, a magnetic tape drive, an optical disk drive, a flash memory, or the like. Removable storage drive 314 may read from and/or write to a removable storage unit 318 in a well-known manner. Removable storage unit 318 may include a floppy disk, a magnetic tape, an optical disk, etc., which may be read by and written to by removable storage drive 314. As will be appreciated by persons skilled in the relevant art, removable storage unit 318 may include a computer usable storage medium having stored therein computer software and/or data.

In alternative implementations, secondary memory 310 may include other similar means for allowing computer programs or other instructions to be loaded into computer system 300. Such means may include, for example, a removable storage unit 322 and an interface 320. Examples of such means may include a program cartridge and cartridge interface (such as that found in video game devices), a removable memory chip (such as an EPROM, or PROM) and associated socket, and other removable storage units 322 and interfaces 320 which allow software and data to be transferred from removable storage unit 322 to computer system 300.

Computer system 300 may also include a communications interface 324. Communications interface 324 allows software and data to be transferred between computer system 300 and external devices. Communications interface 324 may include a modem, a network interface (such as an Ethernet card), a communications port, a PCMCIA slot and card, or the like. Software and data transferred via communications interface 324 may be in the form of signals, which may be electronic, electromagnetic, optical, or other signals capable of being received by communications interface 324. These signals may be provided to communications interface 324 via a communications path 326. Communications path 326 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 318, removable storage unit 322, and a hard disk installed in hard disk drive 312. Computer program medium and computer usable medium may also refer to memories, such as main memory 308 and secondary memory 310, which may be memory semiconductors (e.g. DRAMs, etc.).

Computer programs (also called computer control logic) are stored in main memory 308 and/or secondary memory 310. Computer programs may also be received via communications interface 324. Such computer programs, when executed, enable computer system 300 to implement different embodiments of the present disclosure as discussed herein. In particular, the computer programs, when executed, enable processor device 304 to implement the processes of the present disclosure, such as the operations in method 100 illustrated by flowcharts of FIGS. 1A-1I discussed above. Accordingly, such computer programs represent controllers of computer system 300. Where an exemplary embodiment of method 100 is implemented using software, the software may be stored in a computer program product and loaded into computer system 300 using removable storage drive 314, interface 320, and hard disk drive 312, or communications interface 324.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

### Example

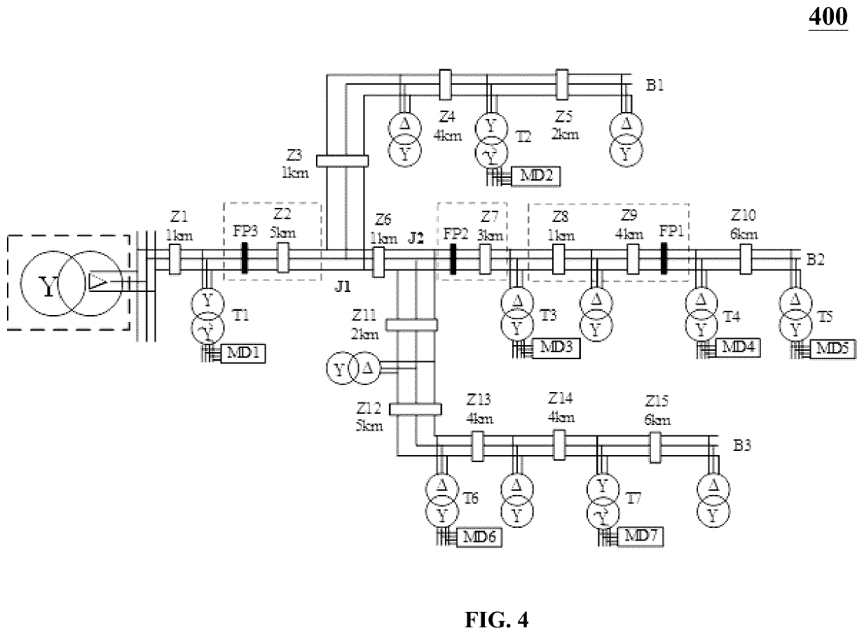

In this example, performance of a method for locating a faulty subsection (similar to method 100) is demonstrated in a distribution network (similar to distribution network 200) for both broken conductor faults and asymmetric short-circuit faults. FIG. 4 shows a schematic of a distribution network with three branches, consistent with one or more exemplary embodiments of the present disclosure. A distribution network 400 includes three branches, a branch B1, a branch B2, and a branch B3. According to FIG. 4, a 1^{st} branch list is equal to [MD1, MD2], a 2^{nd} branch list is equal to [MD1, MD3, MD4, MD5], and a 3^{rd} branch list is equal to [MD1, MD6, MD7].

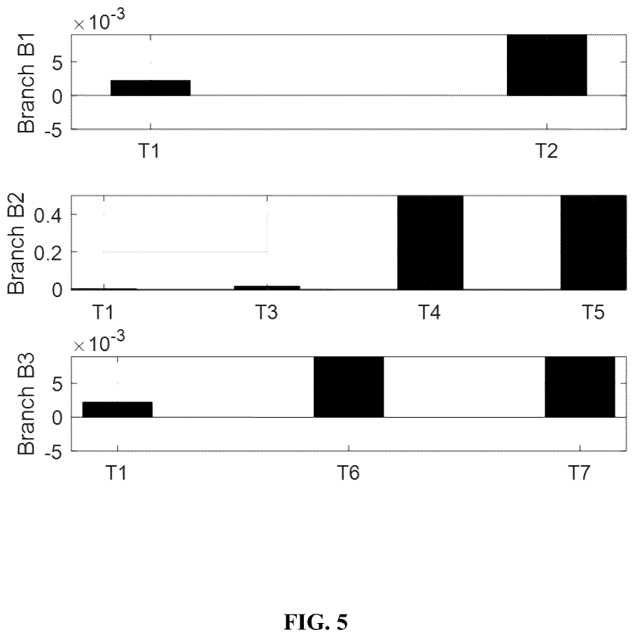

FIG. 5 shows FDI values of different MDs when a broken conductor fault is occurred at a first fault point, consistent with one or more exemplary embodiment of the present disclosure. Secondary FDI values of different MDs are as in FIG. 5 for a broken conductor fault occurring at a fault point FP1 shown in FIG. 4. Referring to FIGS. 4 and 5, since the broken conductor fault is occurred at the branch B2, FDI values of MDs at the branch B2 and after the fault point FP1, i.e., MDs connected to a transformer T4 and a transformer T5 have highest values. As a result, a first MD list and a second MD list are identical and equal to [MD4, MD5], and according to the 2^{nd} branch list, a faulty subsection may be detected before transformer T4, that is, between transformer T4 and a transformer T3.

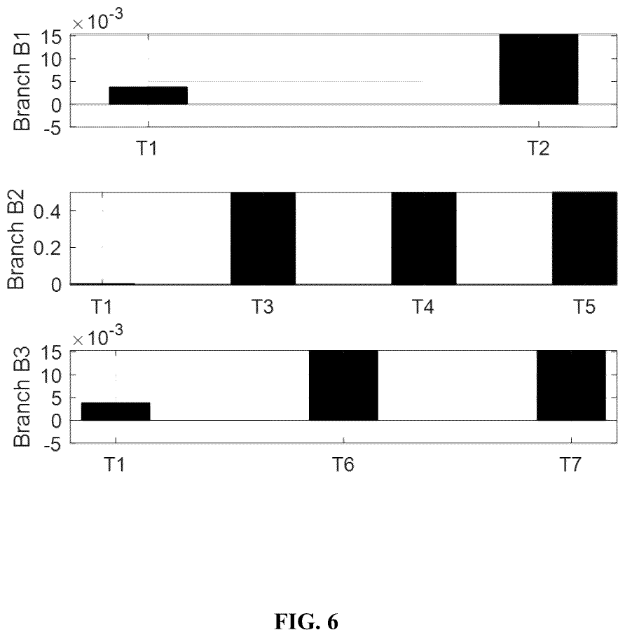

FIG. 6 shows FDI values of different MDs when a broken conductor fault is occurred at a second fault point, consistent with one or more exemplary embodiment of the present disclosure. Secondary FDI values of different MDs are as in FIG. 6 for a broken conductor fault occurring at a fault point FP2 shown in FIG. 4. Referring to FIGS. 4 and 6, since the broken conductor fault is occurred at branch B2, FDI values of MDs at branch B2 and after fault point FP2, i.e., MDs connected to transformer T3, transformer T4, and transformer T5 have highest values. As a result, a first MD list and a second MD list are identical and equal to [MD3, MD4, MD5], and according to the 2^{nd} branch list, a faulty subsection may be detected before transformer T3, that is, between transformer T3 and a junction J₂.

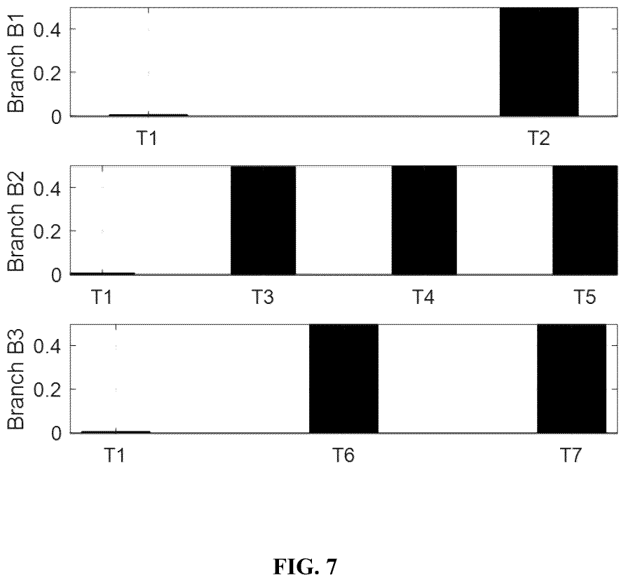

FIG. 7 shows FDI values of different MDs when a broken conductor fault is occurred at a third fault point, consistent with one or more exemplary embodiment of the present disclosure. Secondary FDI values of different MDs are as in FIG. 7 for a broken conductor fault occurring at a fault point FP3 shown in FIG. 4. Referring to FIGS. 4 and 7, since the broken conductor fault is occurred at a common subsection of branch B1, branch B2, and branch B3, FDI values of some MDs at all branches are impacted by the broken conductor fault and have highest values. As a result, a first MD list and a second MD list are identical and equal to [MD2, MD3, MD4, MD5, MD6, MD7]. Therefore, since the first MD list and the second MD list include MDs from two or more branches, a faulty subsection may be detected to be at a common subsection of the two or more branches, that is, according to branch lists, a subsection between a transformer T1 and a junction J₁.

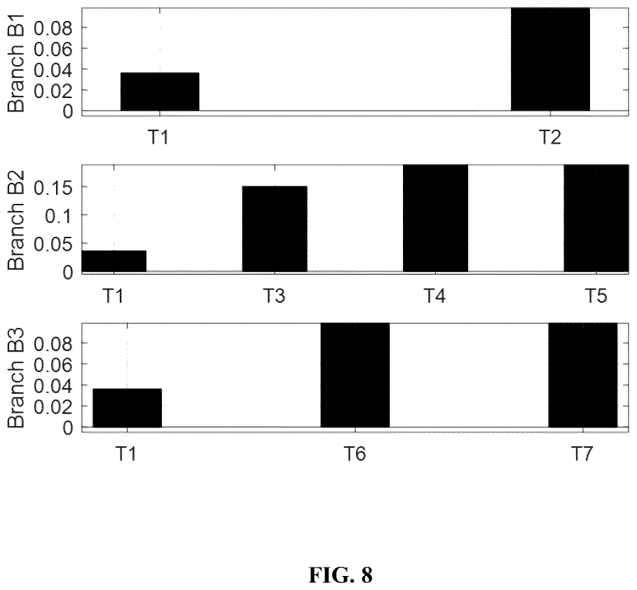

FIG. 8 shows FDI values of different MDs when a phase-to-ground short-circuit fault is occurred at a middle of a line, consistent with one or more exemplary embodiment of the present disclosure. Secondary FDI values of different MDs are as in FIG. 8 for a phase-to-ground short-circuit fault occurring at a fault point FP1 and at 50% of a line between transformer T3 and transformer T4 in FIG. 4. Referring to FIGS. 4 and 8, under the phase-to-ground short-circuit, a fault current is relatively low (about 600 amps). Therefore, secondary FDI values are relatively lower than secondary FDI values under broken conductor faults. Since the phase-to-ground short-circuit fault is occurred at the branch B2, FDI values of MDs at the branch B2 and after the fault point FP1, i.e., MDs connected to a transformer T4 and a transformer T5 have highest values. As a result, a first MD list and a second MD list are identical and equal to [MD4, MD5], and according to the 2^{nd} branch list, a faulty subsection may be detected before transformer T4, that is, between transformer T4 and a transformer T3.

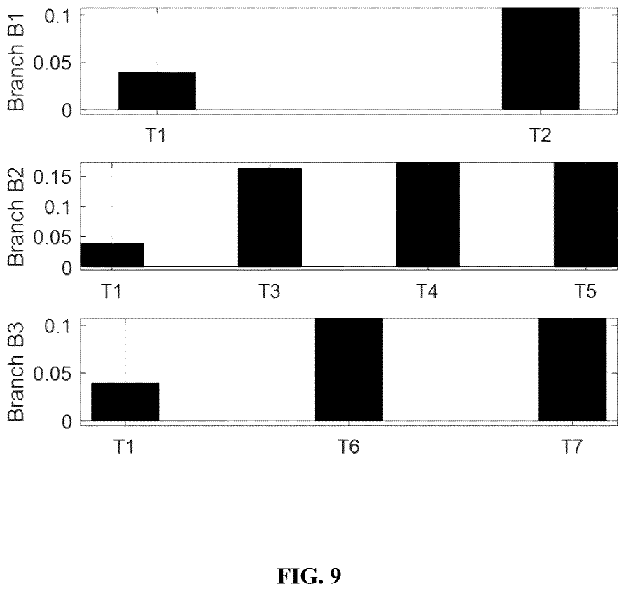

FIG. 9 shows FDI values of different MDs when a phase-to-ground short-circuit fault is occurred at a 10 percent of a line, consistent with one or more exemplary embodiment of the present disclosure. Secondary FDI values of different MDs are as in FIG. 9 for a phase-to-ground short-circuit fault occurring at fault point FP1 and at 10% of a line between transformer T3 and transformer T4. Under the phase-to-ground short-circuit fault, an error current is relatively low (about 640 amps). Since the phase-to-ground short-circuit fault is occurred at the branch B2, FDI values of MDs at the branch B2 have highest values. However, a first MD list and a second MD list are different. The first MD list is equal to [MD3, MD4, MD5] and the second MD list is equal to [MD4, MD5]. As a result, a faulty subsection is between a first MD in the first MD list, that is, device MD3 and a second MD in the first MD list, that is MD4. In addition, the faulty subsection is deduced to be close to the first MD in the first MD list, that is, device MD3.

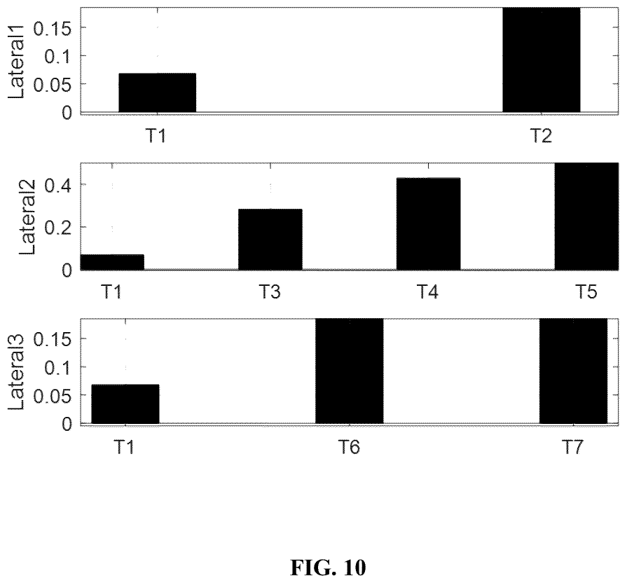

FIG. 10 shows FDI values of different MDs when a phase-to-phase short-circuit fault is occurred, consistent with one or more exemplary embodiment of the present disclosure. Secondary FDI values of different MDs are as in FIG. 10 for a phase-to-phase short-circuit fault occurring at fault point FP1. Since the phase-to-phase short-circuit fault impacts all three branches, FDI values of MDs at all branches have relatively high values. Therefore, a first MD list is equal to [MD2, MD3, MD4, MD5, MD6, MD7]. Therefore, since the first MD list and the second MD list include MDs from two or more branches, a faulty subsection may be detected to be at a common subsection of the two or more branches, that is, according to branch lists a subsection between a transformer T1 and a junction J₁.

While the foregoing has described what may be considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A method for locating a faulty subsection in a distribution network, the method comprising:
measuring, utilizing a plurality of measurement devices (MDs), a plurality of voltage signals from a plurality of distribution transformers in the distribution network;
obtaining, utilizing one or more processors, one or more pre-fault negative sequence components and one or more post-fault negative sequence components from the plurality of voltage signals by:
computing a plurality of primary fault detection indices (FDIs) by computing an i^{th} primary FDI of the plurality of primary FDIs at an i^{th} MD of the plurality of MDs where 1≤i≤N and N is a number of the plurality of MDs, computing the i^{th} primary FDI comprising:
computing a local pre-fault negative sequence component, a local post-fault negative sequence component, a local pre-fault positive sequence component, and a local post-fault positive sequence component from the i^{th} voltage signal;
computing a pre-fault compensated phasor value of the local pre-fault negative sequence component according to an operation defined by the following:
$$\overline{{V}_{2}^{pre}} = \vert {V}_{2}^{pre} \vert ∠ ( {θ}_{V {2}^{pre}} - {θ}_{V {1}^{pre}} )$$
where:
$$\overline{{V}_{2}^{p r e}}$$
is the pre-fault compensated phasor value,
$${V}_{2}^{p r e}$$
is the local pre-fault negative sequence component,
θ_{V2}_{^{pre}} is a phase angle of
$${V}_{2}^{p r e} ,$$
and
θ_{V1}_{^{pre}} is a phase angle of the local pre-fault positive sequence component;
computing a post-fault compensated phasor value of the local post-fault negative sequence component according to an operation defined by the following:
$$\overline{{V}_{2}^{post}} = \vert {V}_{2}^{post} \vert ∠ ( {θ}_{V {2}^{post}} - {θ}_{V {1}^{p o s t}} )$$
where:
$$\overline{{V}_{2}^{post}}$$
is the post-fault compensated phasor value,
$${V}_{2}^{post}$$
is the local post-fault negative sequence component,
θ_{V2}_{^{post}} is a phase angle of
$${V}_{2}^{post} ,$$
and
θ_{V1}_{^{post}} is a phase angle of the local post-fault positive sequence component; and
computing the i^{th} primary FDI according to an operation defined by the following:
$${FDI}_{i} = \frac{\vert \overline{{V}_{2}^{p r e}} - \overline{{V}_{2}^{post}} \vert}{\vert {V}_{1}^{p r e} \vert}$$
where:
FDIᵢ is the i^{th} primary FDI, and
$${V}_{1}^{p r e}$$
is the local pre-fault positive sequence component;
transferring one or more voltage signals of the plurality of voltage signals from one or more MDs of the plurality of MDs to a control center by transferring each of the plurality of voltage signals from a respective MD of the plurality of MDs responsive to a respective primary FDI of the plurality of primary FDIs being larger than a trigger threshold;
obtaining one or more synchronized voltage signals at the control center by synchronizing the one or more voltage signals through synchronizing an m^{th} voltage signal of the one or more voltage signals where 1≤m≤M and M is a number of the one or more voltage signals, synchronizing the m^{th} voltage signal comprising:
computing a phase angle difference between a pre-fault positive sequence component of the m^{th} voltage signal and a pre-fault positive sequence component of a reference voltage signal of the one or more voltage signals; and
obtaining an m^{th} synchronized voltage signal of the one or more synchronized voltage signals by applying a time shift to the m^{th} voltage signal according to an operation defined by the following:
$$Δ t = \frac{Δϕ}{360} \times \frac{{f}_{n}}{{f}_{s}}$$
where:
Δt is the time shift,
Δϕ is the phase angle difference,
fₙ is a frequency of the distribution network, and
fₛ is a sampling frequency of an m^{th} MD of the one or more MDs; and
computing the one or more pre-fault negative sequence components and the one or more post-fault negative sequence components from the one or more synchronized voltage signals; and
detecting, utilizing the one or more processors, the faulty subsection by:
computing one or more secondary FDIs based on the one or more pre-fault negative sequence components and the one or more post-fault negative sequence components;
computing a first threshold and a second threshold by:
obtaining a maximum secondary FDI by finding a maximum value of the one or more secondary FDIs;
setting the first threshold equal to 0.9 FDIₘₐₓ where FDIₘₐₓ is the maximum secondary FDI; and
setting the second threshold equal to 0.95 FDIₘₐₓ;
obtaining a first MD list by:
assigning each of the one or more MDs to the first MD list responsive to a respective secondary FDI of the one or more secondary FDIs being larger than the first threshold; and
sorting the first MD list in an ascending order according to distances of MDs in the first MD list from a high voltage to medium voltage (HV/MV) substation by sorting MDs of the first MD list in each branch of an MV feeder of the distribution network;
obtaining a second MD list by:
assigning each of the one or more MDs to the second MD list responsive to a respective secondary FDI of the one or more secondary FDIs being larger than the second threshold; and
sorting the second MD list in an ascending order according to distances of MDs in the second MD list from the HV/MV substation by sorting MDs of the second MD list in each branch of the MV feeder; and
determining the faulty subsection in the MV feeder responsive to a fault occurrence condition being satisfied, determining the faulty subsection comprising:
determining a first faulty subsection of the MV feeder responsive to a first condition being satisfied, wherein:
the first condition comprises:
the first MD list being identical to the second MD list; and
the first MD list comprising a set of MDs of a single branch of the MV feeder; and
the first faulty subsection comprises a subsection of the MV feeder between a first MD in the first MD list and one of:
a junction in an upstream direction of the MV feeder; or
a closest MD of the plurality of MDs, the closest MD comprising a shortest distance among the plurality of MDs to the first MD in the upstream direction;
determining a second faulty subsection of the MV feeder responsive to a second condition being satisfied, wherein:
the second condition comprises:
the first MD list being identical to the second MD list; and
the first MD list comprising a set of MDs of two or more branches of the MV feeder; and
the second faulty subsection comprises a common subsection of the two or more branches; and
determining a third faulty subsection of the MV feeder responsive to a third condition being satisfied, wherein:
the third condition comprises:
MDs in the first MD list being in a single branch of the MV feeder; and
the first MD list being different from the second MD list; and
the third faulty subsection comprises a subsection of the MV feeder between a first MD in the first MD list and a second MD in the first MD list, the third faulty subsection closer to the first MD than to the second MD.

2. A method for locating a faulty subsection in a distribution network, the method comprising:
measuring, utilizing a plurality of measurement devices (MDs), a plurality of voltage signals from a plurality of distribution transformers in the distribution network;
obtaining, utilizing one or more processors, one or more pre-fault negative sequence components and one or more post-fault negative sequence components from the plurality of voltage signals; and
detecting, utilizing the one or more processors, the faulty subsection based on the one or more pre-fault negative sequence components and the one or more post-fault negative sequence components.

3. The method of claim 2, wherein obtaining the one or more pre-fault negative sequence components and the one or more post-fault negative sequence components comprises:
computing a plurality of primary fault detection indices (FDIs) by computing an i^{th} primary FDI of the plurality of primary FDIs at an i^{th} MD of the plurality of MDs based on an i^{th} voltage signal of the plurality of voltage signals where 1≤i≤N and N is a number of the plurality of MDs;
transferring one or more voltage signals of the plurality of voltage signals from one or more MDs of the plurality of MDs to a control center by transferring each of the plurality of voltage signals from a respective MD of the plurality of MDs responsive to a respective primary FDI of the plurality of primary FDIs being larger than a trigger threshold;
obtaining one or more synchronized voltage signals at the control center by synchronizing the one or more voltage signals; and
computing the one or more pre-fault negative sequence components and the one or more post-fault negative sequence components from the one or more synchronized voltage signals.

4. The method of claim 3, wherein computing the i^{th} primary FDI comprises:
computing a local pre-fault negative sequence component, a local post-fault negative sequence component, a local pre-fault positive sequence component, and a local post-fault positive sequence component from the i^{th} voltage signal;
computing a pre-fault compensated phasor value of the local pre-fault negative sequence component according to an operation defined by the following:
$$\overline{{V}_{2}^{p r e}} = \vert {V}_{2}^{p r e} \vert ∠ ( {θ}_{V {2}^{p r e}} - {θ}_{V {1}^{p r e}} )$$
where:
$$\overline{{V}_{2}^{p r e}}$$
is the pre-fault compensated phasor value,
$${V}_{2}^{p r e}$$
is the local pre-fault negative sequence component,
θ_{V2}_{^{pre}} is a phase angle of
$${V}_{2}^{p r e} ,$$
and
θ_{V1}_{^{pre}} is a phase angle of the local pre-fault positive sequence component;
computing a post-fault compensated phasor value of the local post-fault negative sequence component according to an operation defined by the following:
$$\overline{{V}_{2}^{post}} = \vert {V}_{2}^{post} \vert ∠ ( {θ}_{V {2}^{post}} - {θ}_{V {1}^{p o s t}} )$$
where:
$$\overline{{V}_{2}^{post}}$$
is the post-fault compensated phasor value,
$${V}_{2}^{post}$$
is the local post-fault negative sequence component,
θ_{V2}_{^{post}} is a phase angle of
$${V}_{2}^{post} ,$$
and
θ_{V1}_{^{post}} is a phase angle of the local post-fault positive sequence component; and
computing the i^{th} primary FDI according to an operation defined by the following:
$${FDI}_{i} = \frac{\vert \overline{{V}_{2}^{p r e}} - \overline{{V}_{2}^{post}} \vert}{\vert {V}_{1}^{p r e} \vert}$$
where:
FDIᵢ is the i^{th} primary FDI, and
$${V}_{1}^{p r e}$$
is the local pre-fault positive sequence component.

5. The method of claim 3, wherein synchronizing the one or more voltage signals comprises synchronizing an m^{th} voltage signal of the one or more voltage signals where 1≤m≤M and M is a number of the one or more voltage signals, synchronizing the m^{th} voltage signal comprising:
computing a phase angle difference between a pre-fault positive sequence component of the m^{th} voltage signal and a pre-fault positive sequence component of a reference voltage signal of the one or more voltage signals; and
obtaining an m^{th} synchronized voltage signal of the one or more synchronized voltage signals by applying a time shift to the m^{th} voltage signal according to an operation defined by the following:
$$Δ t = \frac{Δϕ}{360} \times \frac{{f}_{n}}{{f}_{s}}$$
where:
Δt is the time shift,
Δϕ is the phase angle difference,
fₙ is a frequency of the distribution network, and
fₛ is a sampling frequency of an m^{th} MD of the one or more MDs.

6. The method of claim 3, wherein detecting the faulty subsection comprises:
computing one or more secondary FDIs based on the one or more pre-fault negative sequence components and the one or more post-fault negative sequence components;
computing a first threshold and a second threshold based on the one or more secondary FDIs, the first threshold smaller than the second threshold;
obtaining a first MD list by:
assigning each of the one or more MDs to the first MD list responsive to a respective secondary FDI of the one or more secondary FDIs being larger than the first threshold; and
sorting the first MD list in an ascending order according to distances of MDs in the first MD list from a high voltage to medium voltage (HV/MV) substation by sorting MDs of the first MD list in each branch of an MV feeder of the distribution network;
obtaining a second MD list by:
assigning each of the one or more MDs to the second MD list responsive to a respective secondary FDI of the one or more secondary FDIs being larger than the second threshold; and
sorting the second MD list in an ascending order according to distances of MDs in the second MD list from the HV/MV substation by sorting MDs of the second MD list in each branch of the MV feeder; and
determining the faulty subsection in the MV feeder based on the first MD list and the second MD list responsive to a fault occurrence condition being satisfied.

7. The method of claim 6, wherein determining the faulty subsection comprises determining a first faulty subsection of the MV feeder responsive to a first condition being satisfied, wherein:
the first condition comprises:
the first MD list being identical to the second MD list; and
the first MD list comprising a set of MDs of a single branch of the MV feeder; and
the first faulty subsection comprises a subsection of the MV feeder between a first MD in the first MD list and one of:
a junction in an upstream direction of the MV feeder; or
a closest MD of the plurality of MDs, the closest MD comprising a shortest distance among the plurality of MDs to the first MD in the upstream direction.

8. The method of claim 6, wherein determining the faulty subsection further comprises determining a second faulty subsection of the MV feeder responsive to a second condition being satisfied, wherein:
the second condition comprises:
the first MD list being identical to the second MD list; and
the first MD list comprising a set of MDs of two or more branches of the MV feeder; and
the second faulty subsection comprises a common subsection of the two or more branches.

9. The method of claim 6, wherein determining the faulty subsection further comprises determining a third faulty subsection of the MV feeder responsive to a third condition being satisfied, wherein:
the third condition comprises:
MDs in the first MD list being in a single branch of the MV feeder; and
the first MD list being different from the second MD list; and
the third faulty subsection comprises a subsection of the MV feeder between a first MD in the first MD list and a second MD in the first MD list, the third faulty subsection closer to the first MD than to the second MD.

10. The method of claim 6, wherein computing the first threshold and the second threshold comprises:
obtaining a maximum secondary FDI by finding a maximum value of the one or more secondary FDIs;
setting the first threshold equal to 0.9 FDIₘₐₓ where FDIₘₐₓ is the maximum secondary FDI; and
setting the second threshold equal to 0.95 FDIₘₐₓ.

11. The method of claim 6, wherein determining the faulty subsection responsive to the fault occurrence condition comprises determining the faulty subsection responsive to one of:
a maximum value of the one or more secondary FDIs remaining larger than 0.4 for at least 30 seconds; and
an amplitude of a positive sequence component of the one or more voltage signals being less than 0.05 per unit.

12. A system for locating a faulty subsection in a distribution network, the system comprising:
A plurality of measurement devices (MDs) configured to measure a plurality of voltage signals from a plurality of distribution transformers in the distribution network;
a memory having processor-readable instructions stored therein; and
a processor configured to access the memory and execute the processor-readable instructions, which, when executed by the processor configures the processor to perform a method, the method comprising:
obtaining one or more pre-fault negative sequence components and one or more post-fault negative sequence components from the plurality of voltage signals; and
detecting the faulty subsection based on the one or more pre-fault negative sequence components and the one or more post-fault negative sequence components.

13. The system of claim 12, wherein obtaining the one or more pre-fault negative sequence components and the one or more post-fault negative sequence components comprises:
computing a plurality of primary fault detection indices (FDIs) by computing an i^{th} primary FDI of the plurality of primary FDIs at an i^{th} MD of the plurality of MDs based on an i^{th} voltage signal of the plurality of voltage signals where 1≤i≤N and N is a number of the plurality of MDs;
transferring one or more voltage signals of the plurality of voltage signals from one or more MDs of the plurality of MDs to a control center by transferring each of the plurality of voltage signals from a respective MD of the plurality of MDs responsive to a respective primary FDI of the plurality of primary FDIs being larger than a trigger threshold;
obtaining one or more synchronized voltage signals at the control center by synchronizing the one or more voltage signals; and
computing the one or more pre-fault negative sequence components and the one or more post-fault negative sequence components from the one or more synchronized voltage signals.

14. The system of claim 13, wherein computing the i^{th} primary FDI comprises:
computing a local pre-fault negative sequence component, a local post-fault negative sequence component, a local pre-fault positive sequence component, and a local post-fault positive sequence component from the i^{th} voltage signal;
computing a pre-fault compensated phasor value of the local pre-fault negative sequence component according to an operation defined by the following:
$$\overline{{V}_{2}^{p r e}} = \vert {V}_{2}^{p r e} \vert ∠ ( {θ}_{V {2}^{p r e}} - {θ}_{V {1}^{p r e}} )$$
where:
$$\overline{{V}_{2}^{p r e}}$$
is the pre-fault compensated phasor value,
$${V}_{2}^{p r e}$$
is the local pre-fault negative sequence component,
θ_{V2}_{^{pre}} is a phase angle of
$${V}_{2}^{p r e} ,$$
and
θ_{V1}_{^{pre}} is a phase angle of the local pre-fault positive sequence component;
computing a post-fault compensated phasor value of the local post-fault negative sequence component according to an operation defined by the following:
$$\overline{{V}_{2}^{post}} = \vert {V}_{2}^{post} \vert ∠ ( {θ}_{V {2}^{p r e}} - {θ}_{V {1}^{p r e}} )$$
where:
$$\overline{{V}_{2}^{post}}$$
is the post-fault compensated phasor value,
$${V}_{2}^{post}$$
is the local post-fault negative sequence component,
θ_{V2}_{^{post}} is a phase angle of
$${V}_{2}^{post} ,$$
and
θ_{V1}_{^{post}} is a phase angle of the local post-fault positive sequence component; and
computing the i^{th} primary FDI according to an operation defined by the following:
$${FDI}_{i} = \frac{\vert \overline{{V}_{2}^{p r e}} - \overline{{V}_{2}^{post}} \vert}{\vert {V}_{1}^{p r e} \vert}$$
where:
FDI₁ is the i^{th} primary FDI, and
V₁^{pre} is the local pre-fault positive sequence component.

15. The system of claim 13, wherein synchronizing the one or more voltage signals comprises synchronizing an m^{th} voltage signal of the one or more voltage signals where 1 m≤M and M is a number of the one or more voltage signals, synchronizing the m^{th} voltage signal comprising:
computing a phase angle difference between a pre-fault positive sequence component of the m^{th} voltage signal and a pre-fault positive sequence component of a reference voltage signal of the one or more voltage signals; and
obtaining an m^{th} synchronized voltage signal of the one or more synchronized voltage signals by applying a time shift to the m^{th} voltage signal according to an operation defined by the following:
$$Δ t = \frac{Δϕ}{360} \times \frac{{f}_{n}}{{f}_{s}}$$
where:
Δt is the time shift,
Δϕ is the phase angle difference,
fₙ is a frequency of the distribution network, and
fₛ is a sampling frequency of an m^{th} MD of the one or more MDs.

16. The system of claim 13, wherein detecting the faulty subsection comprises:
computing one or more secondary FDIs based on the one or more pre-fault negative sequence components and the one or more post-fault negative sequence components;
computing a first threshold and a second threshold based on the one or more secondary FDIs, the first threshold smaller than the second threshold;
obtaining a first MD list by:
assigning each of the one or more MDs to the first MD list responsive to a respective secondary FDI of the one or more secondary FDIs being larger than the first threshold; and
sorting the first MD list in an ascending order according to distances of MDs in the first MD list from a high voltage to medium voltage (HV/MV) substation by sorting MDs of the first MD list in each branch of an MV feeder of the distribution network;
obtaining a second MD list by:
assigning each of the one or more MDs to the second MD list responsive to a respective secondary FDI of the one or more secondary FDIs being larger than the second threshold; and
sorting the second MD list in an ascending order according to distances of MDs in the second MD list from the HV/MV substation by sorting MDs of the second MD list in each branch of the MV feeder; and
determining the faulty subsection in the MV feeder based on the first MD list and the second MD list responsive to a fault occurrence condition being satisfied.

17. The system of claim 16, wherein determining the faulty subsection comprises determining a first faulty subsection of the MV feeder responsive to a first condition being satisfied, wherein:
the first condition comprises:
the first MD list being identical to the second MD list; and
the first MD list comprising a set of MDs of a single branch of the MV feeder; and
the first faulty subsection comprises a subsection of the MV feeder between a first MD in the first MD list and one of:
a junction in an upstream direction of the MV feeder; or
a closest MD of the plurality of MDs, the closest MD comprising a shortest distance among the plurality of MDs to the first MD in the upstream direction.

18. The system of claim 16, wherein determining the faulty subsection further comprises determining a second faulty subsection of the MV feeder responsive to a second condition being satisfied, wherein:
the second condition comprises:
the first MD list being identical to the second MD list; and
the first MD list comprising a set of MDs of two or more branches of the MV feeder; and
the second faulty subsection comprises a common subsection of the two or more branches.

19. The system of claim 16, wherein determining the faulty subsection further comprises determining a third faulty subsection of the MV feeder responsive to a third condition being satisfied, wherein:
the third condition comprises:
MDs in the first MD list being in a single branch of the MV feeder; and
the first MD list being different from the second MD list; and
the third faulty subsection comprises a subsection of the MV feeder between a first MD in the first MD list and a second MD in the first MD list, the third faulty subsection closer to the first MD than to the second MD.

20. The system of claim 16, wherein:
computing the first threshold and the second threshold comprises:
obtaining a maximum secondary FDI by finding a maximum value of the one or more secondary FDIs;
setting the first threshold equal to 0.9 FDIₘₐₓ where FDIₘₐₓ is the maximum secondary FDI; and
setting the second threshold equal to 0.95 FDIₘₐₓ; and
determining the faulty subsection responsive to the fault occurrence condition comprises determining the faulty subsection responsive to one of:
a maximum value of the one or more secondary FDIs remaining larger than 0.4 for at least 30 seconds; and
an amplitude of a positive sequence component of the one or more voltage signals being less than 0.05 per unit.
